(19) United States
(12) Patent Application Publication
(10) Pub. No.: US 2025/0208189 A1
(43) Pub. Date: Jun. 26, 2025

(54) INSPECTION METHOD FOR LIGHT EMITTING ELEMENT, MANUFACTURING METHOD FOR DISPLAY DEVICE AND INSPECTION DEVICE FOR LIGHT EMITTING ELEMENT

(71) Applicant: Samsung Display Co., LTD., Yongin-si (KR)

(72) Inventor: Chan Woo JOO, Yongin-si (KR)

(21) Appl. No.: 18/952,766

(22) Filed: Nov. 19, 2024

(30) Foreign Application Priority Data
Dec. 20, 2023 (KR) 10-2023-0187489

(51) Int. Cl. G01R 31/26; G01M 11/02; G09G 3/00; H01L 21/66; H10K 59/12

(52) U.S. Cl. CPC G01R 31/2601; G01M 11/0257; G09G 3/006; H01L 22/14; H10K 59/1201

(57) ABSTRACT

A light emitting element inspection method including: forming a plurality of light emitting element rods by etching a plurality of semiconductor material layers stacked on a growth substrate; forming a protective layer covering a portion of a top surface and a portion of side surfaces of the plurality of light emitting element rods and a contact electrode on the protective layer; forming a metal layer on the side surfaces of the plurality of light emitting element rods and on a portion of the growth substrate on which none of the plurality of light emitting elements rods is located; forming a contact pad connected to the metal layer on the growth substrate; and applying a test power to the contact electrode and the contact pad.

### CROSS-REFERENCE TO RELATED APPLICATION

The present application claims priority to and the benefit of Korean Patent Application No. 10-2023-0187489, filed on Dec. 20, 2023, in the Korean Intellectual Property Office, the entire disclosure of which is incorporated by reference herein.

### BACKGROUND

### 1. Field

The present disclosure relates to a light emitting element inspection method, a display device manufacturing method, and a light emitting element inspection device.

### 2. Description of the Related Art

As the information society develops, the demand for display devices for displaying images is increasing in various forms. The display device may be a flat panel display device such as a liquid crystal display, a field emission display, or a light emitting display.

The light emitting display device may be implemented as an organic light emitting display device including an organic light emitting diode element as a light emitting element, an inorganic light emitting display device including an inorganic semiconductor element as a light emitting element, or a micro light emitting diode display device including an ultra-small light emitting diode element (or micro light emitting diode element) as a light emitting element.

In a display device manufactured through a process of bonding a micro light emitting element to a display panel, defect inspection of the micro light emitting element is performed after the display device process is completed. If a defect in the micro light emitting element is discovered after the process of the display device is completed, it is not easy to replace the defective micro light emitting element with a light emitting element of good quality, so that the conventional lighting inspection method has a problem of decreasing process efficiency and a problem of decreasing productivity.

### SUMMARY

Aspects and features of embodiments of the present disclosure are to provide a method and an inspection device for performing a lighting inspection of a light emitting element on a growth substrate.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments, a light emitting element inspection method including: forming a plurality of light emitting element rods by etching a plurality of semiconductor material layers stacked on a growth substrate; forming a protective layer covering a portion of a top surface and a portion of side surfaces of the plurality of light emitting element rods and a contact electrode on the protective layer; forming a metal layer on the side surfaces of the plurality of light emitting element rods and on a portion of the growth substrate on which none of the plurality of light emitting elements rods is located; forming a contact pad connected to the metal layer on the growth substrate; and applying a test power to the contact electrode and the contact pad.

According to one or more embodiments, the forming a plurality of the light emitting element rods includes: sequentially forming a third semiconductor material layer, a second semiconductor material layer, an active material layer, and a first semiconductor material layer on the growth substrate; and patterning the third semiconductor material layer, the second semiconductor material layer, the active material layer, and the first semiconductor material layer to form the plurality of light emitting element rods.

According to one or more embodiments, the forming the protective layer covering the portion of the top surface and the portion of the side surfaces of the plurality of light emitting element rods and the contact electrode on the protective layer includes: forming a photoresist covering at least a portion of the second semiconductor material layer on an entire surface of the growth substrate; applying a protective material layer covering the plurality of light emitting element rods and the photoresist; forming the protective layer covering the top surface of the plurality of light emitting element rods, and side surfaces of the first semiconductor material layer and the active material layer; and forming a through hole in a portion on the top surface of each of the plurality of light emitting element rods of the protective layer and forming the contact electrode covering the through hole.

According to one or more embodiments, the forming the metal layer on the side surfaces of the plurality of light emitting element rods and on the portion of the growth substrate on which none of the plurality of light emitting elements rods is located, includes: forming the metal layer on the entire surface of the growth substrate except for the top surface of the plurality of light emitting element rods using a mask, the metal layer being in direct contact with the second semiconductor material layer of the plurality of light emitting element rods and connected to the plurality of light emitting element rods.

According to one or more embodiments, the applying the test power to the contact electrode and the contact pad includes: supplying the test power to at least a portion of the plurality of light emitting element rods using a probe on one side of the plurality of light emitting element rods; acquiring an image of light emitted from the plurality of light emitting element rods to which the test power is supplied to an other side of the plurality of light emitting element rods by an image sensor; and determining whether the plurality of light emitting element rods are defective by a control portion comparing the acquired image with a pre-stored reference image.

According to one or more embodiments, a display device manufacturing method includes: forming a plurality of light emitting element rods by etching a plurality of semiconductor material layers stacked on a growth substrate; forming a protective layer covering a portion of a top surface and a portion of side surfaces of the plurality of light emitting element rods and a contact electrode on the protective layer; forming a metal layer on the side surfaces of the plurality of light emitting element rods and on a portion of the growth substrate on which none of the plurality of light emitting elements rods is located; forming a contact pad connected to the metal layer on the growth substrate; applying a test power to the contact electrode and the contact pad; transferring a plurality of light emitting elements including the plurality of light emitting element rods, the protective layer, and the metal layer to a circuit board; and forming a common electrode in contact with the metal layer of the plurality of light emitting elements on a side surface of the plurality of light emitting elements.

According to one or more embodiments, the forming the plurality of light emitting element rods includes: sequentially forming a third semiconductor material layer, a second semiconductor material layer, an active material layer, and a first semiconductor material layer on the growth substrate; and forming the plurality of light emitting element rods by patterning the third semiconductor material layer, the second semiconductor material layer, the active material layer, and the first semiconductor material layer.

According to one or more embodiments, the forming the protective layer covering the portion of the top surface and the portion of the side surfaces of the plurality of light emitting element rods and the contact electrode on the protective layer includes: forming a photoresist covering at least a portion of the second semiconductor material layer on an entire surface of the growth substrate; applying a protective material layer covering the plurality of light emitting element rods and the photoresist; forming the protective layer covering the top surface of the plurality of light emitting element rods, and side surfaces of the first semiconductor material layer and the active material layer; and forming a through hole in a portion on the top surface of each of the plurality of light emitting element rods of the protective layer, and forming the contact electrode covering the through hole.

According to one or more embodiments, the forming the metal layer on the side surfaces of the plurality of light emitting element rods and on the portion of the growth substrate on which none of the plurality of light emitting elements rods is located includes: forming the metal layer on the entire surface of the growth substrate except for the top surface of the plurality of light emitting element rods using a mask, the metal layer being in direct contact with the second semiconductor material layer of the plurality of light emitting element rods and connected to the plurality of light emitting element rods.

According to one or more embodiments, the forming the metal layer on the side surfaces of the plurality of light emitting element rods and on the portion of the growth substrate on which none of the plurality of light emitting elements rods is located includes: forming the photoresist covering at least a portion of the third semiconductor material layer on the entire surface of the growth substrate; and forming the metal layer covering the plurality of light emitting element rods and the photoresist.

According to one or more embodiments, between the applying the test power and the transferring the plurality of light emitting elements to the circuit board, the method further includes: removing the photoresist; forming a cover protective layer around the side surfaces and the top surface of the plurality of light emitting element rods; and forming an opening in the cover protective layer exposing the contact electrode.

According to one or more embodiments, a plurality of pixel circuit portions is on the circuit board, wherein each of the plurality of pixel circuit portions includes a pixel electrode located at a top surface of the plurality of pixel circuit portions, and wherein the transferring the plurality of light emitting elements including the plurality of light emitting element rods, the protective layer, and the metal layer to the circuit board includes: placing the contact electrode of the light emitting element on the pixel electrode and electrically connecting and bonding the contact electrode on the circuit board.

According to one or more embodiments, the circuit board further includes a bank around the pixel electrode, wherein the method further includes: forming a light blocking layer on the common electrode overlapping the bank; forming a first wavelength conversion layer in an area corresponding to a first sub-pixel of the display device, forming a second wavelength conversion layer in an area corresponding to a second sub-pixel of the display device, and forming a light transmission layer in an area corresponding to a third sub-pixel of the display device from among areas compartmentalized by the light blocking layer; and forming a first color filter on the first wavelength conversion layer, forming a second color filter on the second wavelength conversion layer, and forming a third color filter on the light transmission layer.

According to one or more embodiments, the common electrode does not overlap the top surface of the light emitting element.

According to one or more embodiments, the applying the test power to the contact electrode and the contact pad includes: supplying the test power to at least a portion of the plurality of light emitting element rods using a probe on one side of the plurality of light emitting element rods; acquiring an image of light emitted from the plurality of light emitting element rods to which the test power is supplied to an other side of the plurality of light emitting element rods by an image sensor; and determining whether the plurality of light emitting element rods is defective by a control portion comparing the image acquired by the image sensor with a reference image.

According to one or more embodiments, a light emitting element inspection device for inspecting illumination of a plurality of light emitting elements on a growth substrate, the light emitting element inspection device including: a contact pad on the growth substrate and electrically connected to a metal layer on side surfaces of the plurality of light emitting elements and a portion of the growth substrate on which none of the plurality of light emitting elements is located; and a probe and a power application portion configured to apply a test power to a contact electrode of the plurality of light emitting elements and the contact pad through the probe.

According to one or more embodiments, the light emitting element inspection device further includes an image sensor on one side of the plurality of light emitting elements to acquire an image of light emitted from the plurality of light emitting elements; and a control portion for determining whether the plurality of light emitting elements is defective by comparing the image acquired by the image sensor with a reference image.

According to one or more embodiments, a light emitting element from among the plurality of light emitting elements includes a second semiconductor layer, a first semiconductor layer, and an active layer between the second semiconductor layer and the first semiconductor layer, and wherein the metal layer is in direct contact with the second semiconductor layer and is spaced from the contact electrode.

According to one or more embodiments, the light emitting element further includes a protective layer around a top surface and a side surface of the first semiconductor layer and a side surface of the active layer, wherein the protective layer includes a through hole in a portion on the top surface of the first semiconductor layer of the protective layer, and wherein the contact electrode is electrically connected to the first semiconductor layer through the through hole.

According to one or more embodiments, the metal layer extends over the protective layer and is around the side surfaces of the first semiconductor layer and the active layer.

However, the effects of the present disclosure are not limited to the aforementioned effects, and various other effects are included in the present specification.

### BRIEF DESCRIPTION OF THE DRAWINGS

FIG. 1 is a perspective view illustrating a display device according to one or more embodiments.

FIG. 2 is a layout diagram illustrating a display device according to one or more embodiments.

FIG. 3 is a block diagram illustrating a display device according to one or more embodiments.

FIG. 4 is an equivalent circuit diagram illustrating a sub-pixel according to one or more embodiments.

FIG. 5 is an equivalent circuit diagram illustrating a sub-pixel according to one or more embodiments.

FIG. 6 is a layout diagram illustrating a plurality of pixels in a display area according to one or more embodiments.

FIG. 7 is a cross-sectional view illustrating a display device taken along the line I1-I1′ of FIG. 6 according to one or more embodiments.

FIG. 8 is an enlarged view of an area A of FIG. 7.

FIGS. 9 and 10 are enlarged views of the area A of FIG. 7 according to one or more embodiments.

FIG. 11 is a flowchart illustrating a method of manufacturing a display device according to one or more embodiments.

FIGS. 12-18 and FIGS. 20-24 are cross-sectional views of each stage of the inspection process of a display device according to one or more embodiments, and FIG. 19 is a top view of a growth substrate according to one or more embodiments.

FIG. 25 is a cross-sectional view of a step of the inspection process to illustrate a light emitting element inspection method according to one or more embodiments.

FIGS. 26-28 are cross-sectional views of each step of the inspection process to illustrate a light emitting element inspection method according to one or more embodiments.

### DETAILED DESCRIPTION

Aspects and features of embodiments of the present disclosure and methods for achieving them will become apparent with reference to the embodiments described in detail below along with the accompanying drawings. However, the present disclosure is not limited to the embodiments disclosed herein and will be implemented in various different forms. The present embodiments are provided only to make the present disclosure complete and to give a complete picture of the scope of the present disclosure to one of ordinary skill in the technical field to which the present disclosure belongs, and the present disclosure may be defined by the scope of the claims and their equivalents.

References to an element or layer as being “on” another element or layer include any interposition of another layer or another element directly above or in the middle of the other element. Throughout the present disclosure, the same reference numerals refer to the same components. The shapes, sizes, proportions, angles, numbers, etc. disclosed in the drawings to illustrate embodiments are examples and do not limit the present disclosure to those shown.

Although terms such as first, second, and the like are used to describe various components, the components are not limited by these terms. Therefore, a first component referred to herein may also be a second component within the technical idea of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, specific embodiments will be described with reference to the accompanying drawings.

Hereinafter, embodiments will be described with reference to the accompanying drawings.

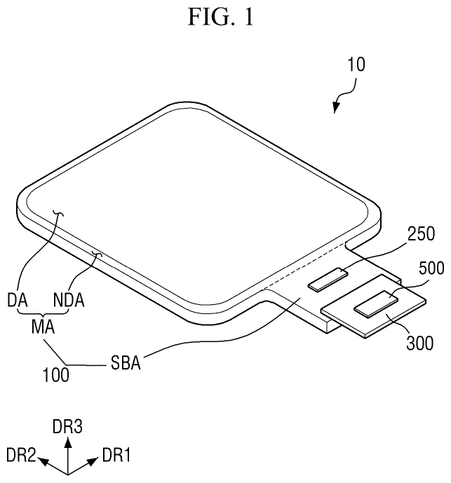

FIG. 1 is a perspective view illustrating a display device according to one or more embodiments.

Referring to FIG. 1, a display device 10 is a device for displaying video or still images, such as mobile phones, smart phones, tablet personal computers, and portable electronic devices such as smart watches, watch phones, mobile communication terminals, electronic notebooks, e-books, portable electronic devices such as portable multimedia players (PMP), navigation, and ultra mobile PCs (UMPC), as well as display screens for a variety of products such as televisions, laptops, monitors, billboards, and/or the internet of things (IoT).

The display device 10 may be a light emitting display device, such as an organic light-emitting display device utilizing an organic light-emitting diode (OLED), a quantum dot light-emitting display device including a quantum dot light-emitting layer, an inorganic light-emitting display device including an inorganic semiconductor, and a miniaturized light-emitting display device utilizing a micro or nano light emitting diode (micro LED or nano LED). Hereinafter, the description focuses on the fact that the display device 10 is a micro-light emitting display device, but the present disclosure is not limited thereto. On the other hand, a micro light emitting diode referred to as a light emitting diode in the following for convenience of explanation.

The display device 10 includes a display panel 100, a display driving circuit 250, a circuit board 300, and a power supply circuit 500.

The display panel 100 may be formed as a rectangular-shaped plane having a short side in the first direction DR1 and a long side in the second direction DR2 that intersects the first direction DR1. A corner where the short side in the first direction DR1 and the long side in the second direction DR2 meet may be rounded to have a suitable curvature (e.g., a predetermined curvature) or may be formed at a right angle. The planar shape of the display panel 100 is not limited to a rectangle, and may be formed in other polygonal, circular, or oval shapes. The display panel 100 may be formed flat but is not limited thereto. For example, the display panel 100 is formed at left and right ends and may include curved portions with a constant curvature or a changing curvature. Additionally, the display panel 100 may be formed to be flexible, such as to be able to be bent, curved, bent, folded, and/or rolled.

The substrate SUB of the display panel 100 may include a main area MA and a sub-area SBA.

The main area MA may include a display area DA that displays an image and a non-display area NDA that is a peripheral area of the display area DA and is around (e.g., surrounding) the display area DA along an edge or a periphery of the display area DA. The display area DA may include a plurality of pixels that display an image. For example, the pixel may include a first sub-pixel that emits first light, a second sub-pixel that emits second light, and a third sub-pixel that emits third light.

The sub-area SBA may protrude from one side of the main area MA in the second direction DR2. Although FIG. 1 illustrates the sub-area SBA being unfolded, the sub-area SBA may be bent, and in this case, may be disposed on the bottom surface of the display panel 100. When the sub-area SBA is bent, it may overlap the main area MA in the third direction DR3, which is the thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached to the display panel 100 using a chip-on-glass (COG) method, a chip-on-plastic (COP) method, or an ultrasonic bonding method but is not limited thereto. For example, the display driving circuit 250 may be attached to the circuit board 300 using a chip-on-film (COF) method.

The circuit board 300 may be attached to one end of the sub-area SBA of the display panel 100. As such, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible printed circuit board (FPCB), a printed circuit board (PCB), or a flexible film such as a chip-on-film (COF).

The power supply circuit 500 (e.g., power supply unit) may generate and/or supply a plurality of panel-driving voltages according to an external power supply voltage. The power supply circuit 500 may be formed as an integrated circuit (IC) and attached to the circuit board 300 using a COF method.

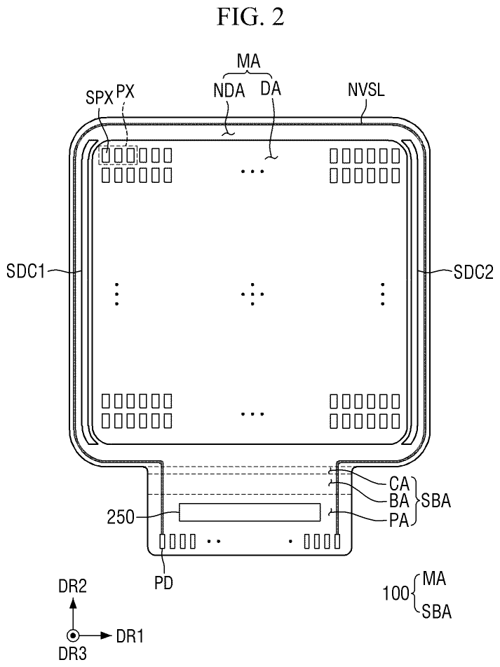

FIG. 2 is a layout diagram illustrating a display device according to one or more embodiments. FIG. 2 illustrates that the sub-area SBA is unfolded without being bent.

Referring to FIG. 2, the display panel 100 may include the main area MA and the sub-area SBA.

The main area MA may include the display area DA that displays an image and the non-display area NDA that is a peripheral area of the display area DA. The display area DA may occupy most of the main area MA. The display area DA may be placed in the center of the main area MA.

The display area DA may include a plurality of pixels PX for displaying an image, and each of the plurality of pixels PX may include a plurality of sub-pixels SPX. A pixel PX may be defined as a sub-pixel group of the smallest unit capable of expressing a white grayscale.

The non-display area NDA may be placed adjacent to the display area DA. The non-display area NDA may be an area outside the display area DA. The non-display area NDA may be arranged to be around (e.g., to surround) the display area DA. The non-display area NDA may be an edge area of the display panel 100.

A first scan driving unit (or a first scan driving portion) SDC1 and a second scan driving unit (or a second scan driving portion) SDC2 may be disposed in the non-display area NDA. The first scan driving unit SDC1 is disposed on one side (for example, the left side) of the display panel 100, and the second scan driving unit SDC2 is disposed on the other side (for example, the right side) of the display panel 100. However, it is not limited thereto. Each of the first scan driving unit SDC1 and the second scan driving unit SDC2 may be electrically connected to the display driving circuit 250 through scan fan-out lines. Each of the first scan driving unit SDC1 and the second scan driving unit SDC2 may receive a scan control signal from the display driving circuit 250, generate scan signals according to the scan control signal, and output them to the scan lines.

The sub-area SBA may protrude from one side of the main area MA in the second direction DR2. The length of the sub-area SBA in the second direction DR2 may be smaller than the length of the main area MA in the second direction DR2. The length in the first direction DR1 of the sub-area SBA is smaller than the length in the first direction DR1 of the main area MA or may be substantially equal to the length in the first direction DR1 of the main area MA. The sub-area SBA may be curved and may be disposed at the lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display driving circuit 250 are disposed. The display driving circuit 250 may be attached to the driving pads of the pad area PA using a conductive adhesive member such as an anisotropic conductive film. The circuit board 300 may be attached to the pads PD of the pad area PA using a conductive adhesive member such as an anisotropic conductive film. One side of the pad area PA may be in contact with the bending area BA.

The bending area BA is a bent area. When the bending area BA is bent, the pad area PA may be disposed below the connection area CA and below the main area MA (e.g., in a thickness direction (e.g., the third direction DR3)). The bending area BA may be disposed between the connection area CA and the pad area PA. One side of the bending area BA may be in contact with the connection area CA, and the other side of the bending area BA may be in contact with the pad area PA.

A non-display power supply line NVSL may be disposed in the non-display area NDA, the connection area CA, the bending area BA, and the pad area PA.

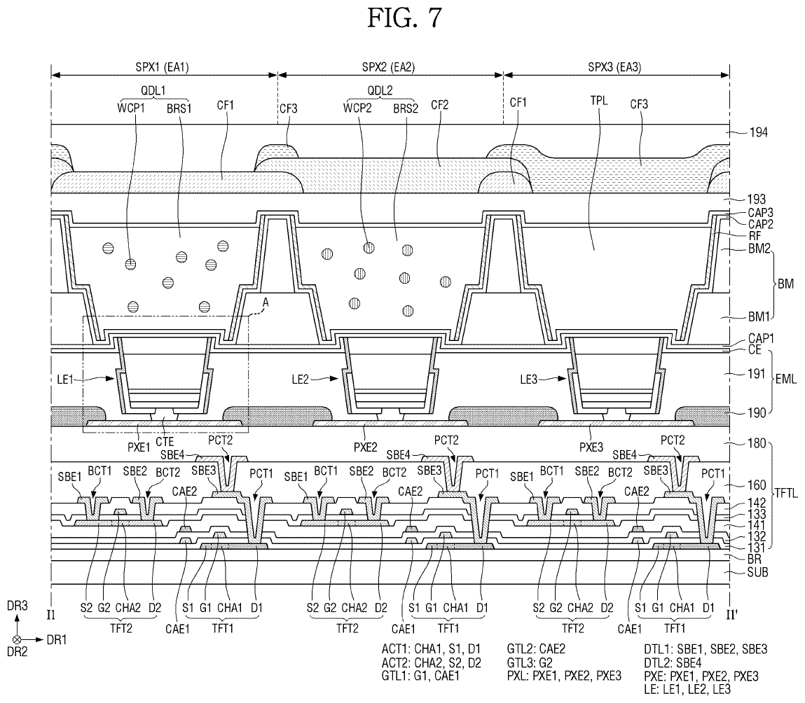

The non-display power supply line NVSL may be disposed on four sides of the display area DA in the non-display area NDA. The non-display power supply line NVSL may be arranged to be around (e.g., to surround) at least three sides of the display area DA. For example, the non-display power supply line NVSL may be around (e.g., may surround) the left, top, and right sides of the display area DA and may be disposed on at least a portion of the lower side. Further, the non-display power supply line NVSL may be disposed outside the first scan driving unit SDC1 and outside the second scan driving unit SDC2. For example, the non-display power supply line NVSL may be disposed on the left side of the first scan driving unit SDC1 and on the right side of the second scan driving unit SDC2. The non-display power supply line NVSL may be disposed at the edge of the first scan driving unit SDC1 and the substrate SUB (see, for example, FIG. 7) and at the edge of the second scan driving unit SDC2 and the substrate SUB. Alternatively, the non-display power supply line NVSL may overlap the first scan driving unit SDC1 and the second scan driving unit SDC2.

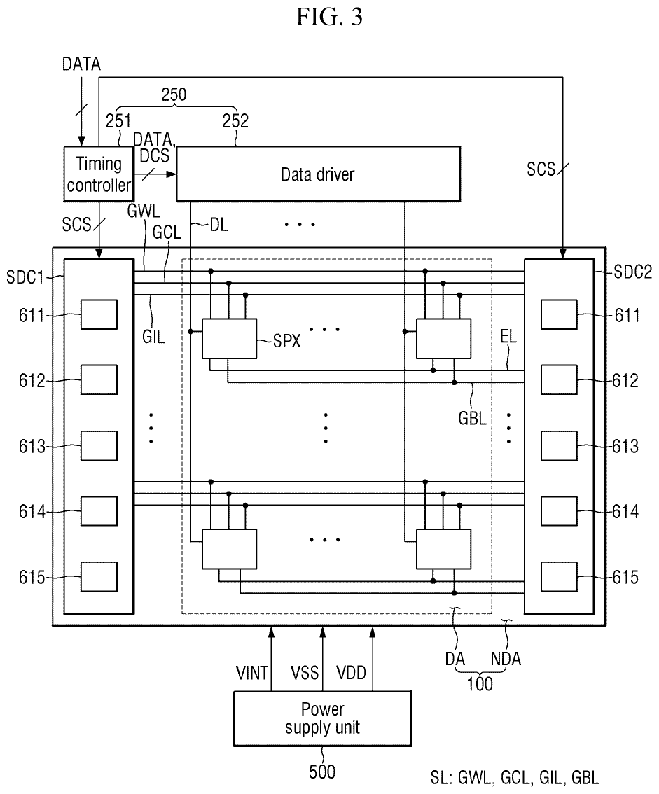

The non-display power supply line NVSL may be disposed at the left and right edges of the connection area CA and the bending area BA. The non-display power supply line NVSL may be connected to a pad PD adjacent to one side edge and a pad PD adjacent to the other side edge from among the pads PD in the pad area PA. The non-display power supply line NVSL may be supplied with a second driving voltage (VSS of FIG. 3) from a power supply circuit (500 of FIG. 1) disposed on the circuit board (300 of FIG. 1).

FIG. 3 is a block diagram illustrating a display device according to one or more embodiments.

Referring to FIG. 3, the display area DA includes a plurality of pixels PX (see FIG. 2), a plurality of scan lines SL, a plurality of emission control lines EL, and a plurality of data lines DL. According to one or more embodiments, each of the plurality of pixels PX includes a plurality of sub-pixels SPX.

The plurality of pixels PX may be arranged in a matrix form in the first direction DR1 and the second direction DR2. For example, the plurality of pixels PX may be arranged along rows and columns of a matrix along the first direction DR1 and the second direction DR2. The plurality of scan lines SL and the plurality of emission control lines EL may extend in the first direction DR1 and may be arranged along the second direction DR2. The plurality of data lines DL may extend in the second direction DR2 and may be arranged along the first direction DR1. The plurality of scan lines SL may include a plurality of write scan lines GWL, a plurality of control scan lines GCL, a plurality of initialization scan lines GIL, and a plurality of bias scan lines GBL.

Each of the plurality of sub-pixels SPX may be connected to a write scan line GWL from among the plurality of write scan lines GWL, a control scan line GCL from among the plurality of control scan lines GCL, an initialization scan line GIL from among the plurality of initialization scan lines GIL, a bias scan line GBL from among the plurality of bias scan lines GBL, an emission control line EL from among the plurality of emission control lines EL, and a data line DL from among the plurality of data lines DL. Each of the plurality of sub-pixels SPX may be supplied with a data voltage of the data line DL according to the write scan signal of the write scan line GWL and may emit light according to the data voltage.

The non-display area NDA includes a first scan driving unit SDC1, a second scan driving unit SDC2, and a display driving circuit 250.

Each of the first scan driving unit SDC1 and the second scan driving unit SDC2 may include a write scan signal output unit 611, a control scan signal output unit 612, an initialization scan signal output unit 613, a bias scan signal output unit 614, and a light emitting signal output unit 615. Each of the write scan signal output unit 611, the control scan signal output unit 612, the initialization scan signal output unit 613, the bias scan signal output unit 614, and the light emitting signal output unit 615 may receive a scan timing control signal SCS from the timing control circuit 251. The write scan signal output unit 611 may generate write scan signals according to the scan timing control signal SCS of the timing control circuit 251 and sequentially output them to the write scan lines GWL. The control scan signal output unit 612 may generate control scan signals according to the scan timing control signal SCS and sequentially output them to the control scan lines GCL. The initialization scan signal output unit 613 may generate initialization scan signals according to the scan timing control signal SCS and sequentially output them to the initialization scan lines GIL. The bias scan signal output unit 614 may generate bias scan signals according to the scan timing control signal SCS and sequentially output them to the bias scan lines GBL. The light emitting signal output unit 615 may generate light emitting control signals according to the scan timing control signal SCS and sequentially output them to the emission control lines EL.

The display driving circuit 250 includes a timing control circuit 251 and a data driving circuit 252.

The data driving circuit 252 may receive digital video data DATA and a data timing control signal DCS from the timing control circuit 251. The data driving circuit 252 converts digital video data DATA into analog data voltages according to the data timing control signal DCS and outputs them to the data lines DL. In this case, the sub-pixels SPX are selected by the write scan signals of the first scan driving unit SDC1 and the second scan driving unit SDC2, and data voltages may be supplied to the selected sub-pixels SPX.

The timing control circuit 251 may receive digital video data DATA and timing signals from an external source. The timing control circuit 251 may generate the scan timing control signal SCS and the data timing control signal DCS to control the display panel 100 according to timing signals. The timing control circuit 251 may output the scan timing control signal SCS to the first scan driving unit SDC1 and the second scan driving unit SDC2. The timing control circuit 251 may output digital video data DATA and a data timing control signal DCS to the data driving circuit 252.

The data driving circuit 252 may receive digital video data DATA and a data timing control signal DCS from the timing control circuit 251.

The data driving circuit 252 may supply respective data signals (e.g., analog data voltages) to the sub-pixels SPX. For example, the data driving circuit 252 may convert the digital video data DATA into analog data voltages according to the data timing control signal DCS and output them to the data lines DL. Sub-pixels SPX may be selected by the write scan signals of the first scan driving unit SDC1 and the second scan driving unit SDC2, and data signals may be supplied to the selected sub-pixels SPX.

The power supply circuit 500 may generate a plurality of panel driving voltages according to an external power supply voltage. For example, the power supply circuit 500 may generate and may supply a first driving voltage VDD, a second driving voltage VSS, and a third driving voltage VINT to the display panel 100.

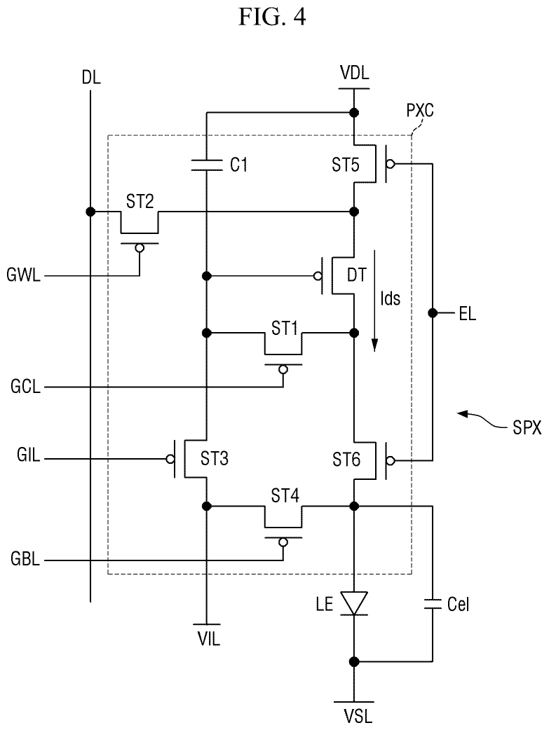

FIG. 4 is an equivalent circuit diagram illustrating a sub-pixel according to one or more embodiments.

Referring to FIG. 4, the sub-pixel SPX according to one or more embodiments may be connected to scan lines GWL, GIL, GCL, and GBL, an emission control line EL, and a data line DL. For example, the sub-pixel SPX may be connected to the write scan line GWL, the initialization scan line GIL, the control scan line GCL, the bias scan line GBL, the emission control line EL, and the data line DL.

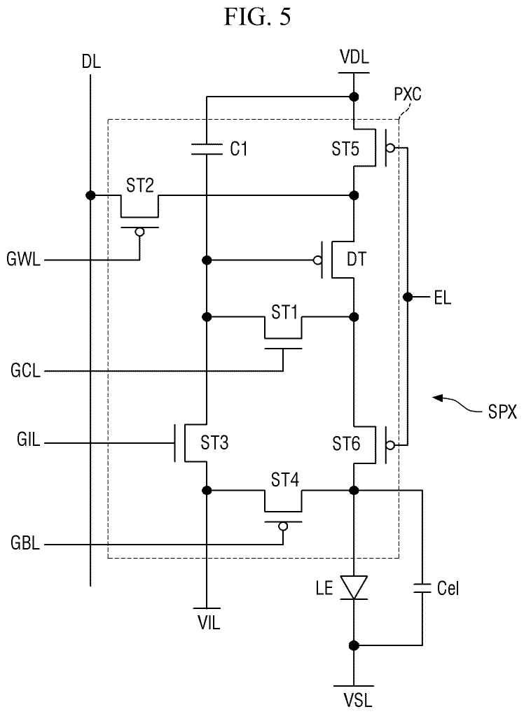

The sub-pixel SPX according to one or more embodiments includes a driving transistor DT, switch elements, a capacitor C1, and a light emitting element LE. The switch elements include first to sixth transistors ST1, ST2, ST3, ST4, ST5, and ST6. The driving transistor DT, switch elements, and capacitor C1 may be referred to as a pixel circuit PXC. The pixel circuit PXC may include a driving transistor DT, at least one switching transistor ST (e.g., transistors ST1, ST2, ST3, ST4, ST5, and ST6), and a capacitor C1. In one or more embodiments, the pixel circuit PXC may include first to sixth transistors ST1, ST2, ST3, ST4, ST5, and ST6 as the switching transistor ST. The configuration of the pixel circuit PXC is not limited to the embodiments of FIGS. 4 and 5 and may be changed in various ways.

The driving transistor DT includes a gate electrode, a first electrode, and a second electrode. The driving transistor DT controls the drain-source current (e.g., hereinafter referred to as “driving current Ids”) flowing between the first electrode and the second electrode according to the data voltage applied to the gate electrode.

The light emitting element LE may be a micro light emitting diode.

The light emitting element LE emits light according to the driving current Ids. The amount of light emitted from the light emitting element LE may be proportional to the driving current Ids. The anode electrode of the light emitting element LE is connected to the first electrode of the fourth transistor ST4 and the second electrode of the sixth transistor ST6, and the cathode electrode may be connected to a second power supply line VSL to which a second power supply voltage is applied. A parasitic capacitance Cel may be formed between the anode electrode and the cathode electrode of the light emitting element LE.

The capacitor C1 is formed between the gate electrode of the driving transistor DT and the first power supply line VDL to which the first power supply voltage is applied. The first power supply voltage may be at a higher level than the second power supply voltage. One electrode of the capacitor C1 may be connected to the gate electrode of the driving transistor DT, and the other electrode may be connected to the first power supply line VDL.

As shown in FIG. 4, the first to sixth transistors ST1, ST2, ST3, ST4, ST5, and ST6 and the driving transistor DT may all be formed as P-type metal oxide semiconductor field effect transistors (P-type MOSFETs). In this case, the active layer of each of the first to sixth transistors ST1, ST2, ST3, ST4, ST5, and ST6 and the driving transistor DT may be formed of polysilicon.

The gate electrode of the second transistor ST2 may be connected to the write scan line GWL, and the gate electrode of the first transistor ST1 may be connected to the control scan line GCL. The gate electrode of the third transistor ST3 may be connected to the initialization scan line GIL, and the gate electrode of the fourth transistor ST4 may be connected to the bias scan line GBL. The gate electrodes of the fifth and sixth transistor ST5 and ST6 may be connected to the emission control line EL. Because the first to sixth transistors ST1, ST2, ST3, ST4, ST5, and ST6 are formed as P-type MOSFET, they may be turned on when a scan signal of the gate low voltage and an emission signal of a low voltage are applied to the control scan line GCL, the initialization scan line GIL, the write scan line GWL, the bias scan line GBL, and the emission control line EL, respectively. One electrode of the third transistor ST3 and one electrode of the fourth transistor ST4 may be connected to an initialization voltage line VIL.

For example, the first transistor ST1 may be connected between the second electrode and the gate electrode of the driving transistor DT. The second transistor ST2 may be connected between the data line DL and the first electrode of the driving transistor DT. The third transistor ST3 may be connected between the initialization voltage line VIL and the gate electrode of the driving transistor DT. The fourth transistor ST4 may be connected between the initialization voltage line VIL and the light-emitting element LE. The fifth transistor ST5 may be connected between the first power supply line VDL and the first electrode of the driving transistor DT. The sixth transistor ST6 may be connected between the second electrode of the driving transistor DT and the light-emitting element LE.

FIG. 5 is an equivalent circuit diagram illustrating a sub-pixel according to one or more embodiments.

Referring to FIG. 5, the driving transistor DT, the second transistor ST2, the fourth transistor ST4, the fifth transistor ST5, and the sixth transistor ST6 are formed of P-type MOSFET, and the first transistor ST1 and the third transistor ST3 may be formed as N-type MOSFET. The active layer of each of the driving transistor DT, the second transistor ST2, the fourth transistor ST4, the fifth transistor ST5, and the sixth transistor ST6 formed as the P-type MOSFET may be formed of polysilicon, and the active layer of each of the first transistor ST1 and the third transistor ST3 formed as the N-type MOSFET may be formed of the oxide semiconductor. In this case, transistors formed of polysilicon and transistors formed of oxide semiconductors may be arranged in different layers.

Because the first transistor ST1 and the third transistor ST3 are formed as N-type MOSFET, the first transistor ST1 may be turned on when a control scan signal with a gate high voltage is applied to the control scan line GCL, and the third transistor ST3 may be turned on when an initialization scan signal with a gate high voltage is applied to the initialization scan line GIL. In comparison, the second transistor ST2, the fourth transistor ST4, the fifth transistor ST5, and the sixth transistor ST6 are formed as P-type MOSFET, so they may be turned on when a scan signal with a gate low voltage and an emission signal (e.g., with a low voltage) are applied to the write scan line GWL, the bias scan line GBL, and the emission control line EL, respectively.

Alternatively, the fourth transistor ST4 in FIG. 4 may be formed of the N-type MOSFET. In this case, the active layer of each fourth transistor ST4 may be formed of the oxide semiconductor. When the fourth transistor ST4 is formed of N-type MOSFET, it may be turned on when a bias scan signal of a gate high voltage is applied to the bias scan line GBL.

In one or more embodiments, the first to sixth transistors ST1, ST2, ST3, ST4, ST5, and ST6 and the driving transistor DT may all be formed as N-type MOSFET. In this case, the active layer of each of the first to sixth transistors ST1, ST2, ST3, ST4, ST5, and ST6 and the driving transistor DT may be formed of an oxide semiconductor.

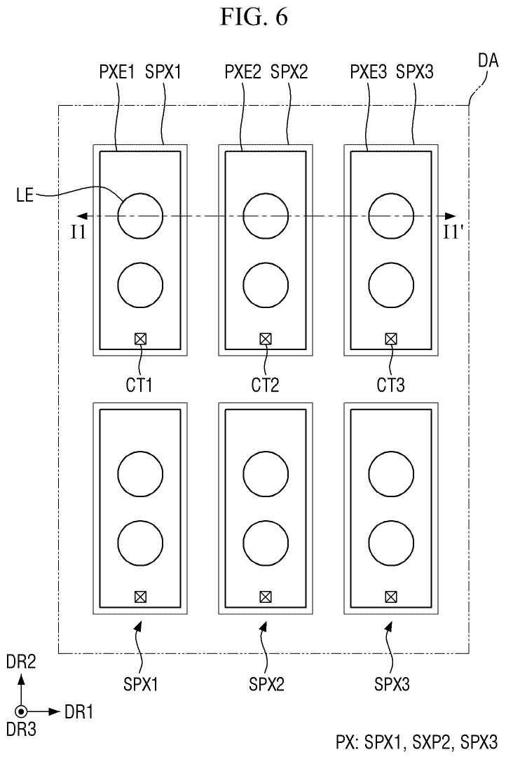

FIG. 6 is a layout diagram illustrating a plurality of pixels in a display area according to one or more embodiments.

Referring to FIG. 6, each of the plurality of pixels PX in the display area DA may include a first sub-pixel SPX1, a second sub-pixel SPX2, and a third sub-pixel SPX3.

A plurality of pixels PX may be arranged in a matrix form. In each of the plurality of pixels PX, the first sub-pixel SPX1, the second sub-pixel SPX2, and the third sub-pixel SPX3 may be arranged along the first direction DR1.

The first sub-pixel SPX1 may emit light of the first color, the second sub-pixel SPX2 may emit light of the second color, and the third sub-pixel SPX3 may emit light of the third color. Here, the first color light may be light in a red wavelength band, the second color light may be light in a green wavelength band, and the third color light may be light in a blue wavelength band. For example, the blue wavelength band may indicate that the main peak wavelength of the light is contained in the wavelength band of approximately 370 nm to 460 nm, and the green wavelength band may indicate that the main peak wavelength of light is contained in the wavelength band of approximately 480 nm to 560 nm, and the red wavelength band may indicate that the main peak wavelength of light is contained in the wavelength band of approximately 600 nm to 750 nm.

Each of the first to third sub-pixels SPX1 to SPX3 may include a pixel electrode PXE and one or more light emitting elements LE.

The pixel electrode PXE may have a rectangular planar shape with a short side in the first direction DR1 and a long side in the second direction DR2, but the present disclosure is not limited thereto.

The pixel electrode PXE may include a first pixel electrode PXE1, a second pixel electrode PXE2, and a third pixel electrode PXE3. The first pixel electrode PXE1 may be electrically connected to the second electrode of the fourth transistor (ST4 in FIGS. 4 and 5) and the second electrode of the sixth transistor (ST6 in FIGS. 4 and 5) of the first subpixel SPX1 through a first connection hole CT1. The second pixel electrode PXE2 may be electrically connected to the second electrode of the fourth transistor (ST4 in FIGS. 4 and 5) and the second electrode of the sixth transistor (ST6 in FIGS. 4 and 5) of the second sub-pixel SPX2 through a second connection hole CT2. The third pixel electrode PXE3 may be electrically connected to the second electrode of the fourth transistor (ST4 in FIGS. 4 and 5) and the second electrode of the sixth transistor (ST6 in FIGS. 4 and 5) of the third sub-pixel SPX3 through a third connection hole CT3.

A plurality of light emitting elements LE may be disposed on each of the first pixel electrode PXE1, the second pixel electrode PXE2, and the third pixel electrode PXE3. The same number of light emitting elements LE may be disposed on each of the first pixel electrode PXE1, the second pixel electrode PXE2, and the third pixel electrode PXE3. For example, two light emitting elements LE may be disposed on each of the first pixel electrode PXE1, the second pixel electrode PXE2, and the third pixel electrode PXE3. Alternatively, one light emitting element LE may be disposed on each of the first pixel electrode PXE1, the second pixel electrode PXE2, and the third pixel electrode PXE3.

The plurality of light emitting elements LE may emit third light, that is, light in a blue wavelength band, but is not limited thereto. For example, the light emitting element LE disposed on the first pixel electrode PXE1 emits light in the blue wavelength band, and the light emitting element LE disposed on the second pixel electrode PXE2 emits light in the green wavelength band, and the light emitting element LE disposed on the third pixel electrode PXE3 emits light in the red wavelength band.

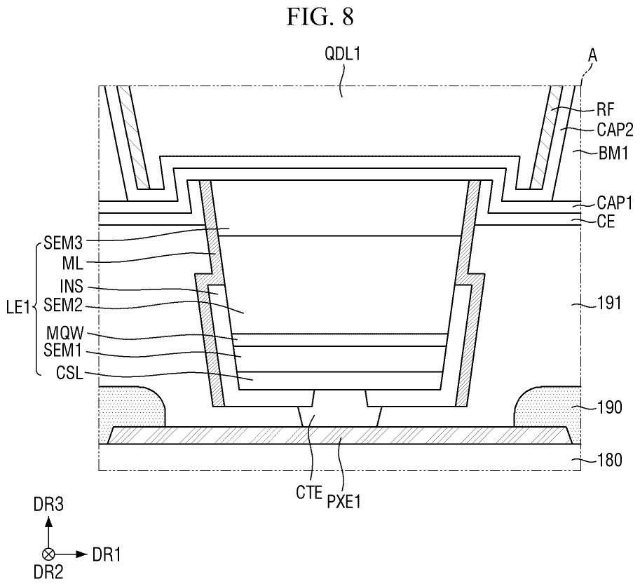

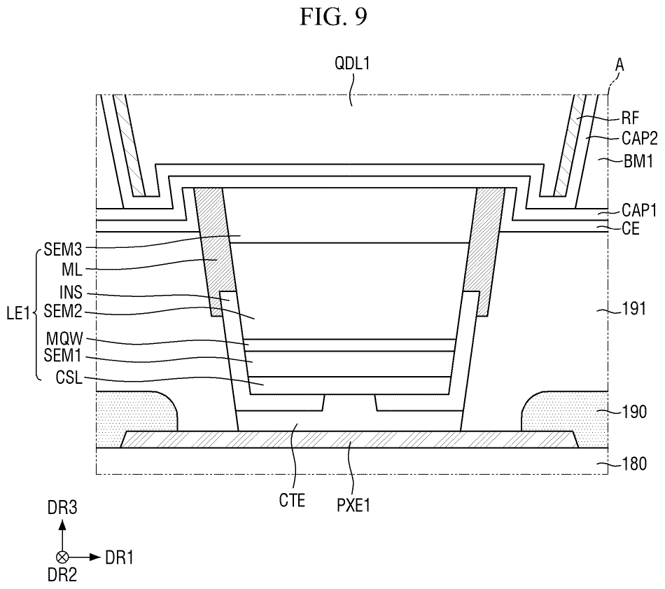

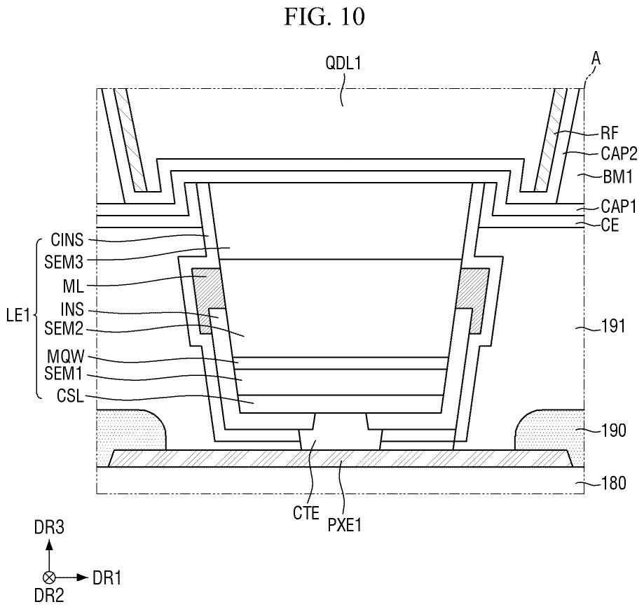

FIG. 7 is a cross-sectional view of a display device taken along the line I1-I1′ of FIG. 6. FIG. 8 is an enlarged view of an area A of FIG. 7. FIGS. 9 and 10 are enlarged views of the area A of FIG. 7 according to one or more embodiments.

Referring to FIGS. 7 and 8, a substrate SUB may be made of an insulating material such as glass, polymer resin, and/or the like. If the substrate SUB is made of polymer resin, it may be a flexible substrate that may be stretched. The polymer resin may be acrylic resin, epoxy resin, phenolic resin, polyamide resin, polyimide resin, and/or the like.

A barrier film BR may be disposed on the substrate SUB. The barrier film BR is a membrane for protecting the transistors of a thin film transistor layer TFTL and the light emitting element LE of a light emitting element layer EML from moisture penetrating through the substrate SUB, which is vulnerable to moisture penetration. The barrier film BR may be composed of a plurality of inorganic films stacked alternately. For example, the barrier film BR may be formed as a multilayer of alternating inorganic films of one or more of a silicon nitride layer, a silicon oxynitride layer, a silicon oxide layer, a titanium oxide layer, and/or an aluminium oxide layer.

A first thin film transistor TFT1 may be disposed on the barrier film BR. The first thin film transistor TFT1 may be either the fourth transistor ST4 or the sixth transistor ST6 shown in FIG. 5. The first thin film transistor TFT1 may include a first active layer ACT1 and a first gate electrode G1.

The first active layer ACT1 of the first thin film transistor TFT1 may be disposed on the barrier film BR. The first active layer ACT1 of the first thin film transistor TFT1 may include polycrystalline silicon, single crystalline silicon, low-temperature polycrystalline silicon, and/or amorphous silicon.

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be disposed on one side of the first channel area CHA1, and the first drain area D1 may be disposed on the other side of the first channel area CHA1. The first source area S1 and the first drain area D1 may be areas that do not overlap with the first gate electrode G1 in the third direction DR3. The first source area S1 and the first drain area D1 may be areas in which the silicon semiconductor is doped with ions to make it conductive.

A first gate insulating film 131 may be disposed on the first channel area CHA1, the first source area S1, and the first drain area D1 of the first thin film transistor TFT1 and the barrier film BR. The first gate insulating film 131 may be formed of an inorganic film, for example, a silicon nitride layer, a silicon oxynitride layer, a silicon oxide layer, a titanium oxide layer, and/or an aluminium oxide layer.

A first gate metal layer GTL1 may be disposed on the first gate insulating film 131. The first gate metal layer GTL1 may include the first gate electrode G1 of the first thin film transistor TFT1 and a first capacitor electrode CAE1. The first gate electrode G1 may overlap the first active layer ACT1 in the third direction DR3. In FIG. 7, the first gate electrode G1 and the first capacitor electrode CAE1 are shown to be spaced (e.g., disposed apart) from each other, but the first gate electrode G1 and the first capacitor electrode CAE1 may be connected to each other. The first gate metal layer GTL1 may be formed as a single layer or multiple layers of molybdenum (Mo), aluminium (Al), chromium (Cr), gold (Au), titanium (Ti), nickel (Ni), neodymium (Nd), and/or copper (Cu), and/or an alloy thereof.

A second gate insulating film 132 may be disposed on the first gate electrode G1 of the first thin film transistor TFT1, the first capacitor electrode CAE1, and the first gate insulating film 131. The second gate insulating film 132 may be formed of an inorganic film, for example, a silicon nitride layer, a silicon oxynitride layer, a silicon oxide layer, a titanium oxide layer, and/or an aluminium oxide layer.

A second gate metal layer GTL2 may be disposed on the second gate insulating film 132. The second gate metal layer GTL2 may include a second capacitor electrode CAE2. The second capacitor electrode CAE2 may overlap the first capacitor electrode CAE1 of the capacitor C1 in the third direction DR3. Because the second gate insulating film 132 has a suitable permittivity (e.g., a predetermined permittivity), a capacitor (C1 in FIG. 5) may be formed by the first capacitor electrode CAE1, the second capacitor electrode CAE2, and the second gate insulating film 132 disposed between them. The second gate metal layer GTL2 may be formed as a single layer or multiple layers of molybdenum (Mo), aluminium (Al), chromium (Cr), gold (Au), titanium (Ti), nickel (Ni), neodymium (Nd), and/or copper (Cu), and/or an alloy thereof.

A first interlayer insulating film 141 may be disposed on the second capacitor electrode CAE2 and the second gate insulating film 132. The first interlayer insulating film 141 may be formed of an inorganic film, such as a silicon nitride layer, a silicon oxynitride layer, a silicon oxide layer, a titanium oxide layer, and/or an aluminium oxide layer.

A second thin film transistor TFT2 may be disposed on the first interlayer insulating film 141. The second thin film transistor TFT2 may be either the first transistor ST1 or the third transistor ST3 shown in FIG. 5. The second thin film transistor TFT2 may include a second active layer ACT2 and a second gate electrode G2.

The second active layer ACT2 of the second thin film transistor TFT2 may be disposed on the first interlayer insulating film 141. The second active layer ACT2 may include an oxide semiconductor. For example, the second active layer ACT2 may include IGZO (indium (In), gallium (Ga), zinc (Zn) and oxygen (O)), IGZTO (indium (In), gallium (Ga), zinc (Zn), tin (Sn), and/or oxygen (O)), and/or IGTO (indium (In), gallium (Ga), tin (Sn) and oxygen (O)).

The second active layer ACT2 may include a second channel area CHA2, a second source area S2, and a second drain area D2. The second channel area CHA2 may be an area that overlaps the second gate electrode G2 in the third direction DR3. The second source area S2 may be disposed on one side of the second channel area CHA2, and the second drain area D2 may be disposed on the other side of the second channel area CHA2. The second source area S2 and the second drain area D2 may be areas that do not overlap the second gate electrode G2 in the third direction DR3. The second source area S2 and the second drain area D2 may be areas in which the oxide semiconductor is doped with ions to make it conductive.

A third gate insulating film 133 may be disposed on the second active layer ACT2 of the second thin film transistor TFT2 and the first interlayer insulating film 141. The third gate insulating film 133 may be formed of an inorganic film, for example, a silicon nitride layer, a silicon oxynitride layer, a silicon oxide layer, a titanium oxide layer, and/or an aluminium oxide layer.

A third gate metal layer GTL3 may be disposed on the third gate insulating film 133. The third gate metal layer GTL3 may include the second gate electrode G2 of the second thin film transistor TFT2. The second gate electrode G2 may overlap the second active layer ACT2 in the third direction DR3. The third gate metal layer GTL3 may be formed as a single layer or multiple layers of molybdenum (Mo), aluminium (Al), chromium (Cr), gold (Au), titanium (Ti), nickel (Ni), neodymium (Nd), and/or copper (Cu), and/or an alloy thereof.

A second interlayer insulating film 142 may be disposed on the second gate electrode G2 of the second thin film transistor TFT2 and the third gate insulating film 133. The second interlayer insulating film 142 may be formed of an inorganic film, for example, a silicon nitride layer, a silicon oxynitride layer, a silicon oxide layer, a titanium oxide layer, and/or an aluminium oxide layer.

A first data metal layer DTL1 may be disposed on the second interlayer insulating film 142. The first data metal layer DTL1 may include a first source connection electrode SBE3, a second source connection electrode SBE1, and a third source connection electrode SBE2. The first source connection electrode SBE3 may be connected to the first drain area D1 of the first active layer ACT1 through a first source contact hole PCT1 penetrating a first gate insulating film 131, a second gate insulating film 132, a first interlayer insulating film 141, a third gate insulating film 133, and a second interlayer insulating film 142. A second source connection electrode SBE1 may be connected to the second source area S2 of the second active layer ACT2 through the second source connection contact hole BCT1 penetrating the second interlayer insulating film 142 and the third gate insulating film 133. The third source connection electrode SBE2 may be connected to the second drain area D2 of the second active layer ACT2 through the third source connection contact hole BCT2 penetrating the second interlayer insulating film 142 and third gate insulating film 133. The first data metal layer DTL1 may be formed as a single layer or multiple layers of molybdenum (Mo), aluminium (Al), chromium (Cr), gold (Au), titanium (Ti), nickel (Ni), neodymium (Nd), and/or copper (Cu), and/or an alloy thereof. For example, the first data metal layer DTL1 may include a first layer made of titanium (Ti), a second layer made of aluminum (Al), and a third layer made of titanium (Ti).

A first organic layer 160 may be disposed to flatten the step due to the first thin film transistor TFT1 and the second thin film transistor TFT2 and the first source connection electrode SBE3, the second source connection electrode SBE1, and the third source connection electrode SBE2 on the second interlayer insulating film 142. The first organic layer 160 may be formed from an organic film such as acrylic resin, epoxy resin, phenolic resin, polyamide resin, polyimide resin, and/or the like.

A second data metal layer DTL2 may be disposed on the first organic layer 160. The second data metal layer DTL2 may include a fourth source connection electrode SBE4. The fourth source connection electrode SBE4 may be connected to the first source connection electrode SBE3 through a second pixel contact hole PCT2 penetrating the first organic layer 160. The second data metal layer DTL2 may be formed as a single layer or multiple layers of molybdenum (Mo), aluminium (Al), chromium (Cr), gold (Au), titanium (Ti), nickel (Ni), neodymium (Nd), and/or copper (Cu), and/or an alloy thereof. For example, the second data metal layer DTL2 may include a first layer made of titanium (Ti), a second layer made of aluminum (Al), and a third layer made of titanium (Ti).

A second organic layer 180 may be disposed on the fourth source connection electrode SBE4 and the first organic layer 160. The second organic layer 180 may be formed of an organic film such as acrylic resin, epoxy resin, phenolic resin, polyamide resin, polyimide resin, and/or the like.

A light emitting element layer EML may be disposed on the second organic layer 180. The light emitting element layer EML may include pixel electrodes PXE1, PXE2, and PXE3, light emitting elements LE, a common electrode CE, and a contact electrode CTE.

A pixel electrode layer PXL may be disposed on the second organic layer 180. The pixel electrode layer PXL may include a first pixel electrode PXE1, a second pixel electrode PXE2, and a third pixel electrode PXE3. In the first sub-pixel SPX1, the first pixel electrode PXE1 may be connected to the fourth source connection electrode SBE4 through a first connection hole (CT1 in FIG. 6) penetrating the second organic layer 180. In the second sub-pixel SPX2, the second pixel electrode PXE2 may be connected to the fourth source connection electrode SBE4 through a second connection hole (CT2 in FIG. 6) penetrating the second organic layer 180. In the third sub-pixel SPX3, the third pixel electrode PXE3 may be connected to the fourth source connection electrode SBE4 through a third connection hole (CT3 in FIG. 6) penetrating the second organic layer 180.

In the first sub-pixel SPX1, the first pixel electrode PXE1 may be connected to the first source area S1 or the first drain area D1 of the first thin film transistor TFT1 through the first source connection electrode SBE3 and the fourth source connection electrode SBE4. Therefore, a voltage controlled by the first thin film transistor TFT1 in the first sub-pixel SPX1 may be applied to the first pixel electrode PXE1.

In addition, in the second sub-pixel SPX2, the second pixel electrode PXE2 may be connected to the first source area S1 or the first drain area D1 of the first thin film transistor TFT1 through the first source connection electrode SBE3 and the fourth source connection electrode SBE4. Therefore, a voltage controlled by the first thin film transistor TFT1 in the second sub-pixel SPX2 may be applied to the second pixel electrode PXE2.

Further, in the third sub-pixel SPX3, the third pixel electrode PXE3 may be connected to the first source area S1 or the first drain area D1 of the first thin film transistor TFT1 through the first source connection electrode SBE3 and the fourth source connection electrode SBE4. Therefore, a voltage controlled by the first thin film transistor TFT1 in the third sub-pixel SPX3 may be applied to the third pixel electrode PXE3.

The pixel electrode PXE (e.g., pixel electrodes PXE1, PXE2, PXE3) may be formed as a single layer or multiple layers of molybdenum (Mo), aluminium (Al), chromium (Cr), gold (Au), titanium (Ti), nickel (Ni), neodymium (Nd), and/or copper (Cu), and/or an alloy thereof. Because the pixel electrodes PXE serve to connect the first light emitting element LE1, the second light emitting element LE2, or the third light emitting element LE3, it is desirable to lower the surface resistance of the pixel electrodes PXE to reduce the contact resistance between the pixel electrodes PXE and the first light emitting element LE1, the second light emitting element LE2, or the third light emitting element LE3. For example, the pixel electrode layer PXL may be made of copper (Cu) with low sheet resistance.

The bank layer 190 may be disposed to cover the edges of the first pixel electrode PXE1, the second pixel electrode PXE2, and the third pixel electrode PXE3. The bank layer 190 may be formed of an organic layer such as an acrylic resin, an epoxy resin, a phenolic resin, a polyamide resin, a polyimide resin, and/or the like. The bank layer 190 may include a light blocking material to prevent light from the light emitting element LE of one sub-pixel SPX from proceeding to the neighboring sub-pixel SPX. For example, the bank layer 190 may include an inorganic black pigment such as carbon black and/or an organic black pigment.

The light emitting element LE may be disposed on the first pixel electrode PXE1, the second pixel electrode PXE2, and the third pixel electrode PXE3 that are exposed and not covered by the bank layer 190. One or more light emitting elements LE may be disposed on each of the first pixel electrode PXE1, the second pixel electrode PXE2, and the third pixel electrode PXE3.

As shown in FIG. 7, the light emitting elements LE (e.g., light emitting elements LE1, LE2, LE3) may be disposed in each of the first light emitting area EA1, the second light emitting area EA2, and the third light emitting area EA3. The light emitting element LE may be a vertical light emitting diode element extending in the third direction DR3. That is, the length of the light emitting element LE in the third direction DR3 may be greater than the length in the horizontal direction. The length in the horizontal direction indicates the length in the first direction DR1 and/or the length in the second direction DR2. For example, the length of the light emitting element LE in the third direction DR3 may be approximately 1 μm to 5 μm. However, the present disclosure is not limited to this, and the length of the light emitting element LE in the third direction DR3 may be equal to or smaller than the length in the horizontal direction.

The light emitting element LE may be a micro light emitting diode element. Referring to FIG. 8, the light emitting element LE may include a current spreading layer CSL, a first semiconductor layer SEM1, and an active layer MQW, a second semiconductor layer SEM2, and a third semiconductor layer SEM3 sequentially stacked in the thickness direction of the substrate SUB, that is, in the third direction DR3. In one or more embodiments, an electron blocking layer may be disposed between the first semiconductor layer SEM1 and the active layer MQW. In addition, a superlattice layer may be disposed between the active layer MQW and the second semiconductor layer SEM2. Further, the current spreading layer CSL and/or the third semiconductor layer SEM3 may be omitted.

Additionally, the light emitting element LE may further include a protective layer INS and a metal layer ML.

The light emitting element LE may have a cylindrical shape, a disk shape, or a rod shape where the height is longer than the width. However, it is not limited to this, and the light emitting element LE may be shaped like a rod, wire, tube, and/or the like, or may have a polygonal shape such as a cube, cuboid, hexagon, and/or hexagonal column, or may have a shape that extends in one direction but has a partially inclined outer surface (e.g., outer peripheral or circumferential surface).

The current spreading layer CSL is a layer to increase the light extraction efficiency and may be formed of a transparent conductive oxide (TCO) such as indium tin oxide (ITO) and/or indium zinc oxide (IZO) to transmit light but it is not limited thereto.

The first semiconductor layer SEM1 may be disposed on the current spreading layer CSL. The length of the bottom surface of the first semiconductor layer SEM1 in the first direction DR1 or the length in the second direction DR2 may be less than the length of the contact electrode CTE in the first direction DR1 or the length in the second direction DR2. The first semiconductor layer SEM1 may be made of GaN doped with a first conductivity type dopant such as Mg, Zn, Ca, Ba, and/or the like.

The active layer MQW may be disposed on the first semiconductor layer SEM1. The active layer MQW may emit light by recombining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. In this case, the well layer may be formed of InGaN, and the barrier layer may be formed of GaN or AlGaN but is not limited thereto. Alternatively, the active layer MQW may have a structure in which semiconductor materials having a high energy band gap and semiconductor materials having a low energy band gap are alternately stacked with each other, and may include other Group III to V semiconductor materials according to the wavelength range of emitted light.

When the active layer MQW includes InGaN, the color of the emitted light may vary depending on the content of indium (In). For example, as the content of indium (In) increases, the wavelength band of light emitted by the active layer MQW may shift to the red wavelength band, and as the content of indium (In) decreases, the wavelength band of light emitted by the active layer MQW may shift to the blue wavelength band. For example, the content of indium (In) in the active layer MQW of the light emitting element LE that emits the third light (e.g., light in the blue wavelength band) may be approximately 10 wt % to 20 wt %.

The second semiconductor layer SEM2 may be disposed on the active layer MQW. The second semiconductor layer SEM2 may be doped with a second conductivity type dopant such as Si, Ge, Se, Sn, and/or the like. For example, the second semiconductor layer SEM2 may be n-GaN doped with n-type Si.

The electron blocking layer may be disposed between the first semiconductor layer SEM1 and the active layer MQW. The electron blocking layer may be a layer to suppress or prevent too many electrons from flowing into the active layer MQW. For example, the electron blocking layer may be AlGaN and/or p-AlGaN doped with p-type Mg. The electron blocking layer may be omitted.

The superlattice layer may be disposed between the active layer MQW and the second semiconductor layer SEM2. The superlattice layer may be a layer for relieving stress between the second semiconductor layer SEM2 and the active layer MQW. For example, the superlattice layer may be formed of InGaN and/or GaN. The superlattice layer may be omitted.

The protective layer INS may be a membrane to protect the outer surface (e.g., outer peripheral or circumferential surface) of the light emitting element LE.

The protective layer INS may be around (e.g., may surround) the side surfaces of the current spreading layer CSL, the first semiconductor layer SEM1, and the active layer MQW, and may be around (e.g., may surround) a portion of the side surface of the second semiconductor layer SEM2. The protective layer INS may expose at least a portion of the side surface of the second semiconductor layer SEM2. Further, the protective layer INS may expose the side surface of the third semiconductor layer SEM3. The protective layer INS may be formed of an inorganic film, for example, a silicon nitride layer, a silicon oxynitride layer, a silicon oxide layer, a titanium oxide layer, and/or an aluminium oxide layer.

The metal layer ML may directly contact and may be around (e.g., may surround) at least a portion of the side of the second semiconductor layer SEM2 on which the protective layer INS is not disposed and the third semiconductor layer SEM3. The metal layer ML may extend over the protective layer INS and may be around (e.g., may surround) at least a portion of the side surface of the second semiconductor layer SEM2, the active layer MQW, the first semiconductor layer SEM1, and the current spreading layer CSL over the protective layer INS. Accordingly, the metal layer ML is not in direct contact with the active layer MQW, the first semiconductor layer SEM1, and the current spreading layer CSL, as well as the contact electrode CTE.

The metal layer ML may include molybdenum (Mo), aluminium (Al), chromium (Cr), gold (Au), titanium (Ti), nickel (Ni), neodymium (Nd) and/or copper (Cu).

In one or more embodiments, referring to FIG. 9, the metal layer ML may be around (e.g., may surround) at least a portion of the side surface of the second semiconductor layer SEM2 and the side surface of the third semiconductor layer SEM3. The metal layer ML may not be disposed on the sides of the current spreading layer CSL, the first semiconductor layer SEM1, and the active layer MQW.

In one or more embodiments, referring to FIG. 9, the side surfaces of the contact electrode CTE and the light emitting element LE may be aligned with each other and placed in a straight line.

In one or more embodiments, referring to FIG. 10, the metal layer ML may be around (e.g., may surround) at least a portion of the side surface of the second semiconductor layer SEM2. The metal layer ML may not be around (e.g., may not surround) at least a portion of the side surface of the third semiconductor layer SEM3. The metal layer ML may be in direct contact with at least a portion of the side surface of the second semiconductor layer SEM2. In one or more embodiments, the metal layer ML may be around (e.g., may surround) at least a portion of the side surface of the third semiconductor layer SEM3.

The light emitting element LE may further include a cover protective layer CINS around (e.g., surrounding) the side surfaces of the plurality of semiconductor layers and the side surfaces and top surfaces of the current spreading layer CSL on the metal layer ML and the protective layer INS. The cover protective layer CINS may have an opening on the top surface of the light emitting element LE. The contact electrode CTE may be exposed through the opening.

Referring to FIGS. 8 to 10, a metal layer ML may be around (e.g., may surround) at least a portion of the side surface of the second semiconductor layer SEM2. The metal layer ML may be in direct contact with the second semiconductor layer SEM2.

A contact electrode CTE may be disposed between the pixel electrode PXE and the light emitting element LE. The contact electrode CTE connects the light emitting element LE and the pixel electrode PXE overlapping in the thickness direction of the light emitting element LE.

The contact electrode CTE may be disposed on the pixel electrode PXE. The contact electrode CTE may serve as a bonding metal for adhering the pixel electrodes PXE and the light emitting elements LE. Alternatively, the contact electrode CTE may further include a separate connection electrode between the pixel electrodes PXE.

The contact electrodes CTE may be formed in multiple layers. The contact electrode CTE may include a connection portion and a reflective portion that is spaced (e.g., spaced apart) from the pixel electrode PXE, and the connection portion is disposed on the pixel electrode PXE to bond the pixel electrode PXE and the light emitting element LE. The reflective portion may be disposed closer to the first semiconductor layer SEM1 (or the current spreading layer CSL) than the connection portion. The reflective portion serves to reflect light emitted from the light emitting element LE that travels in the downward direction rather than the upward direction, thereby improving the light emission efficiency of the light emitting element LE. The reflective portion may include more highly reflective metal material, such as AI, than the connection portion.

The contact electrode CTE may be in contact with the pixel electrodes PXE1, PXE2, and PXE3. The contact electrode CTE may be in direct contact with the current spreading layer CSL of the light emitting element LE. The protective layer INS may have a through hole so that the contact electrode CTE is in direct contact with the current spreading layer CSL. The current spreading layer CSL may be exposed through the through hole. The current spreading layer CSL and the contact electrode CTE exposed through the through hole may be in direct contact.

The through hole overlaps the contact electrode CTE in the thickness direction of the light emitting element LE, and the width of the through hole may be equal to or smaller than the width of the contact electrode CTE.

The contact electrode CTE may include molybdenum (Mo), aluminum (Al), chromium (Cr), gold (Au), titanium (Ti), nickel (Ni), neodymium (Nd), and/or copper (Cu).

A third organic layer 191 may be disposed to cover a portion of the side surfaces of the bank layer 190 and the plurality of light emitting elements LE. The third organic layer 191 may be formed of an organic layer such as an acrylic resin, an epoxy resin, a phenolic resin, a polyamide resin, a polyimide resin, and/or the like.

The third organic layer 191 may be disposed to cover a portion of the side surface of each of the plurality of light emitting elements LE. The third organic layer 191 may be disposed lower than the plurality of light emitting elements LE to expose upper portions of the light emitting elements LE.

The third organic layer 191 is a layer for flattening the steps caused by the plurality of light emitting elements LE. In one or more embodiments, the third organic layer 191 may be formed as a single layer but may be formed as multiple layers.

The common electrode CE may be disposed on the side surface of each of the plurality of light emitting elements LE and the top surface of the third organic layer 191. The common electrode CE may be a common layer commonly formed in the first sub-pixel SPX1, the second sub-pixel SPX2, and the third sub-pixel SPX3. Because the common electrode CE contacts, the side of the light emitting element LE and is not disposed on the top surface of the light emitting element LE, the common electrode CE may be a conductive material that does not transmit light but is not limited thereto. The common electrode CE may be made of a transparent conductive material (TCO), such as indium tin oxide (ITO) and/or indium zinc oxide (IZO), which may transmit light. The common electrode CE may be disposed on the top surface of each of the plurality of light emitting elements LE.

In one or more embodiments, the pixel electrode PXE may be referred to as an anode electrode or a first electrode, and the common electrode CE may be referred to as a cathode electrode or a second electrode.

A first capping layer CAP1 may be disposed on the common electrode CE. The first capping layer CAP1 may be formed of an inorganic layer film, for example, a silicon nitride layer, a silicon oxynitride layer, a silicon oxide layer, a titanium oxide layer, and/or an aluminium oxide layer.

A light blocking layer BM, a first light conversion layer QDL1, a second light conversion layer QDL2, and a light transmission layer TPL may be disposed on the first capping layer CAP1. The first light conversion layer QDL1, the second light conversion layer QDL2, and the light transmission layer TPL may be formed by partitioning the light blocking layer BM. Therefore, the first light conversion layer QDL1 is disposed on the first capping layer CAP1 in the first sub-pixel SPX1, and the second light conversion layer QDL2 is disposed on the first capping layer CAP1 in the second sub-pixel SPX2, and a light transmission layer TPL may be disposed on the first capping layer CAP1 in the third sub-pixel SPX3. The light blocking layer BM may overlap the bank layer 190 in the third direction DR3 and may not overlap the plurality of light emitting elements LE.

The first light conversion layer QDL1 may convert a portion of the third light (e.g., light in the blue wavelength band) incident from the light emitting element LE into first light (e.g., light in the red wavelength band). The first light conversion layer QDL1 may include a first base resin BRS1 and first wavelength conversion particles WCP1. The first base resin BRS1 may include a light-transmitting organic material. For example, the first base resin BRS1 may include an epoxy-based resin, an acrylic-based resin, a cardo-based resin, and/or an imide-based resin. The first wavelength conversion particle WCP1 may convert a portion of the third light (e.g., light in the blue wavelength band) incident from the light emitting element LE into first light (e.g., light in the red wavelength band). The first wavelength conversion particle WCP1 may be a quantum dot (QD), a quantum rod, a fluorescent material, and/or a phosphorescent material.

The second light conversion layer QDL2 may convert a portion of the third light (e.g., light in the blue wavelength band) incident from the light emitting element LE into second light (e.g., light in the green wavelength band). It may include a second base resin BRS2 and a second wavelength conversion particle WCP2. The second base resin BRS2 may include a light transmission organic material. For example, the second base resin BRS2 may include an epoxy-based resin, an acrylic-based resin, a cado-based resin, and/or an imide-based resin. The second wavelength conversion particle WCP2 may convert a portion of the third light (e.g., light in the blue wavelength band) incident from the light emitting element LE into second light (e.g., light in the green wavelength band). The second wavelength conversion particle WCP2 may be a quantum dot (QD), a quantum rod, a fluorescent material, and/or a phosphorescent material.

The light transmission layer TPL may include a light transmission organic material. For example, the light transmission layer TPL may include epoxy-based resin, acrylic-based resin, cardo-based resin, and/or imide-based resin.

The light blocking layer BM may include a first light blocking layer BM1 and a second light blocking layer BM2 that are sequentially stacked. A length of the first direction DR1 or a length of the second direction DR2 of the first light blocking layer BM1 may be wider than a length of the first direction DR1 or a length of the second direction DR2 of the second light blocking layer BM2. The first light blocking layer BM1 and the second light blocking layer BM2 may be formed of an organic layer such as an acrylic resin, an epoxy resin, a phenolic resin, a polyamide resin, a polyimide resin, and/or the like. The first light blocking layer BM1 and the second light blocking layer BM2 may include a light blocking material to prevent light from the light emitting element LE of one sub-pixel SPX from proceeding to the neighboring sub-pixel SPX. For example, the first light blocking layer BM1 and the second light blocking layer BM2 may include an inorganic black pigment such as carbon black or an organic black pigment.

The second capping layer CAP2 may be disposed on the first capping layer CAP1 and the light blocking layer BM. The second capping layer CAP2 may be disposed on the side and top surfaces of the light blocking layer BM. That is, the second capping layer CAP2 may be disposed on the side of the first light blocking layer BM1 and on the side and top surfaces of the second light blocking layer BM2.

A reflective layer RF may be disposed between the light blocking layer BM and the first light conversion layer QDL1, between the light blocking layer BM and the second light conversion layer QDL2, and between the light blocking layer BM and the light transmission layer TPL. The reflective layer RF may be disposed on a second capping layer CAP2 disposed on the side of the first light blocking layer BM1 and the side of the second light blocking layer BM2. The reflective layer RF serves to reflect light traveling in the lateral direction from the first light conversion layer QDL1, the second light conversion layer QDL2, and the light transmission layer TPL.

The reflective layer RF may include a highly reflective metal material such as aluminum (Al). The thickness of the reflective layer RF may be approximately 0.1 μm.

Alternatively, the reflective layer RF may include M (where M is an integer greater than or equal to 2) pairs of first and second layers having different refractive indices to act as Distributed Bragg Reflectors (DBR). In this case, M first layers and M second layers may be arranged alternately. The first layer and the second layer may be formed of an inorganic film, for example, a silicon nitride layer, a silicon oxynitride layer, a silicon oxide layer, a titanium oxide layer, and/or an aluminum oxide layer.

The third capping layer CAP3 may be disposed on the second capping layer CAP2, the first light conversion layer QDL1, the second light conversion layer QDL2, and the light transmission layer TPL. The third capping layer CAP3 may be formed of an inorganic film, for example, a silicon nitride layer, a silicon oxynitride layer, a silicon oxide layer, a titanium oxide layer, and/or an aluminium oxide layer. The first light conversion layer QDL1, the second light conversion layer QDL2, and the light transmission layer TPL may be encapsulated by the first capping layer CAP1, the second capping layer CAP2, and the third capping layer CAP3.

A fourth organic layer 193 may be disposed on the second capping layer CAP2. The fourth organic layer 193 may be formed of acrylic resin, epoxy resin, phenolic resin, polyamide resin, polyimide resin, and/or the like.

A plurality of color filters CF1, CF2, and CF3 may be disposed on the fourth organic layer 193. The plurality of color filters CF1, CF2, and CF3 may include first color filters CF1, second color filters CF2, and third color filters CF3.

The first color filter CF1 disposed in the first sub-pixel SPX1 may transmit the first light (e.g., light in the red wavelength band) and absorb or block the third light (e.g., light in the blue wavelength band). Therefore, the first color filter CF1 may transmit the first light (e.g., light in the red wavelength band) converted by the first light conversion layer QDL1 from among the third light (e.g., light in the blue wavelength band) emitted by the light emitting element LE and absorb or block the third light (e.g., light in the blue wavelength band) not converted by the first light conversion layer QDL1. Thus, the first sub-pixel SPX1 may emit the first light (e.g., light in the red wavelength band).

The second color filter CF2 disposed in the second sub-pixel SPX2 may transmit the second light (e.g., light in the green wavelength band) and absorb or block the third light (e.g., light in the blue wavelength band). Therefore, the second color filter CF2 may transmit the second light (e.g., light in the green wavelength band) converted by the second light conversion layer QDL2 from among the third light (e.g., light in the blue wavelength band) emitted by the light emitting element LE and absorb or block the third light (e.g., light in the blue wavelength band) not converted by the second light conversion layer QDL2. Thus, the second sub-pixel SPX2 may emit the second light (e.g., light in the green wavelength band).

The third color filter CF3 disposed in the third sub-pixel SPX3 may transmit third light (e.g., light in the blue wavelength band). Therefore, the third color filter CF3 may transmit the third light (e.g., light in the blue wavelength band) emitted from the light emitting element LE through the light transmission layer TPL. Accordingly, the third sub-pixel SPX3 may emit the third light (e.g., light in the blue wavelength band).

The first color filter CF1, the second color filter CF2, and the third color filter CF3 overlapping in the third direction DR3 may overlap with the bank layer 190 and the light blocking layer BM in the third direction DR3.

A fifth organic layer 194 for planarization may be disposed on the plurality of color filters CF1, CF2, and CF3. The fifth organic layer 194 may be formed of acrylic resin, epoxy resin, phenolic resin, polyamide resin, polyimide resin, and/or the like.

Referring to FIGS. 7 and 8, the light emitting element LE includes a metal layer ML around (e.g., surrounding) at least a portion of the side surface of the second semiconductor layer SEM2, and the metal layer ML may be in contact with the common electrode CE and the side of the second semiconductor layer SEM2. Therefore, the common electrode CE may not cover the top surface of the light emitting element LE. The common electrode CE may also be formed by a non-transparent conductive material.

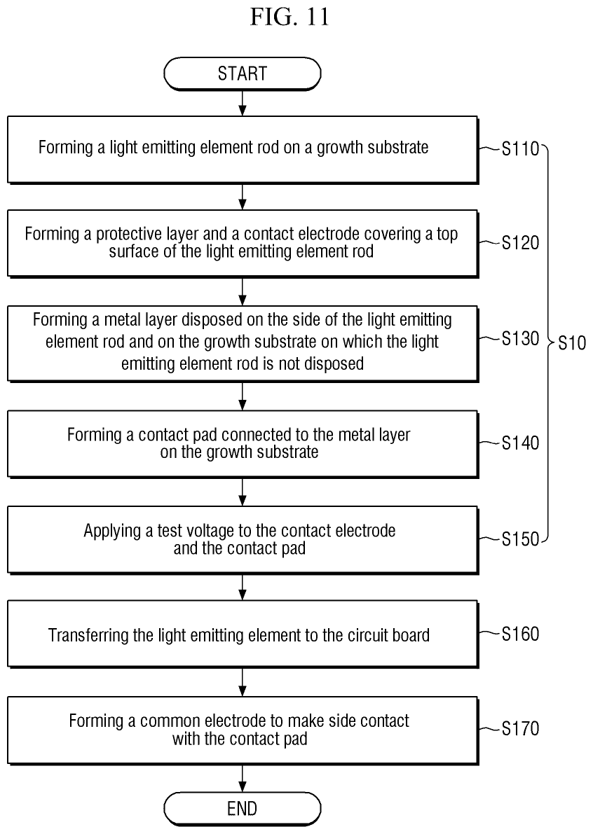

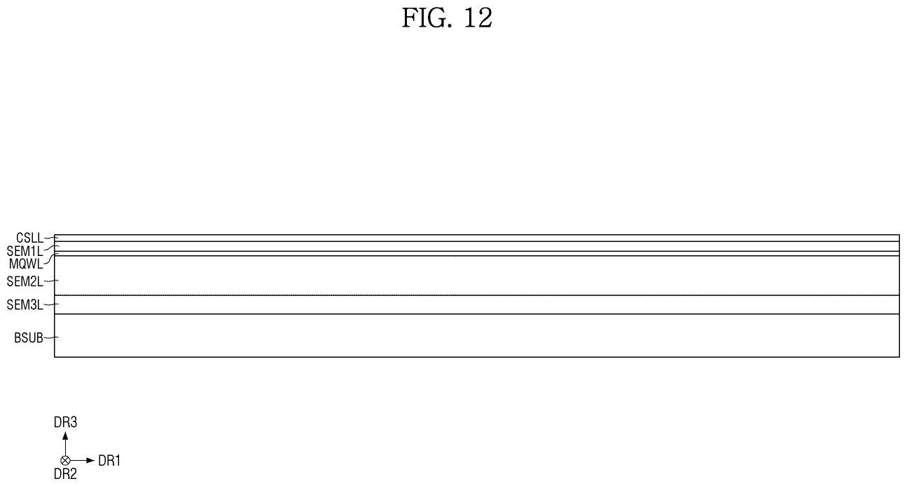

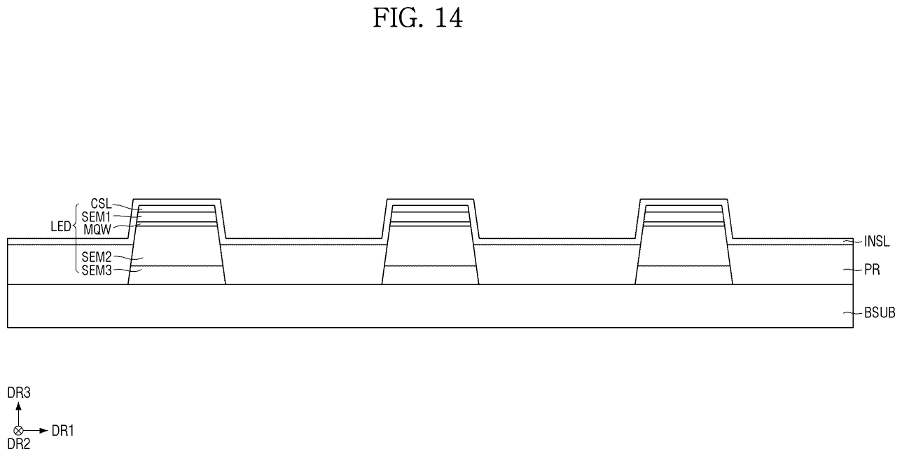

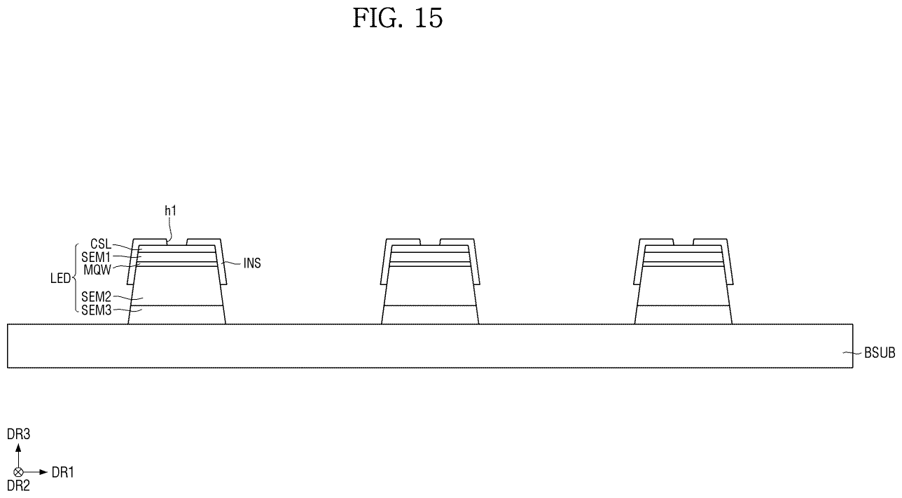

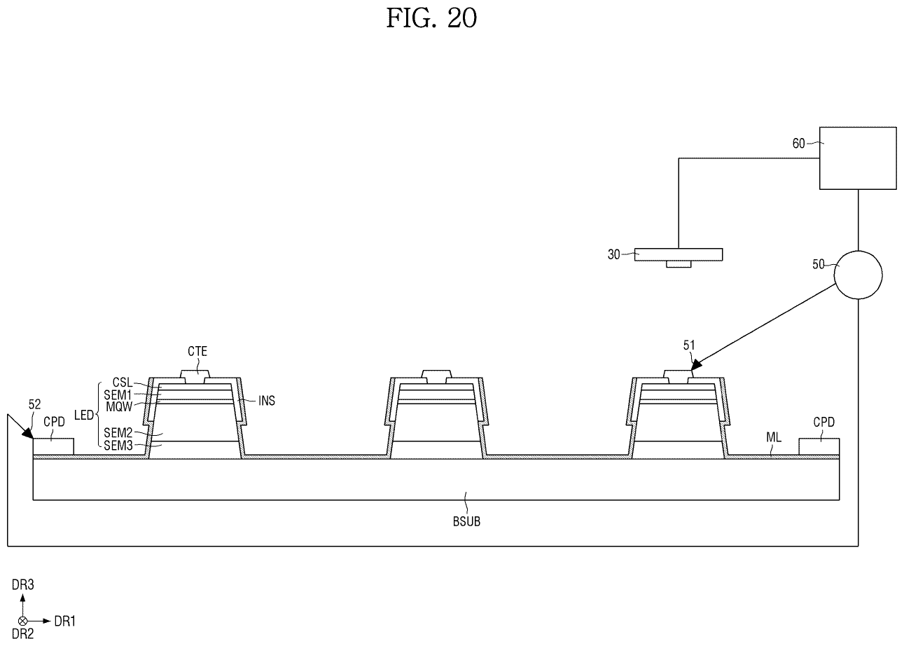

FIG. 11 is a flowchart illustrating a method of manufacturing a display device according to one or more embodiments. FIGS. 12-18 and FIGS. 20-24 are cross-sectional views of each stage of the inspection process of a display device according to one or more embodiments, and FIG. 19 is a top view of a growth substrate according to one or more embodiments. Additionally, as described above, FIG. 20 is a cross-sectional view of each stage of the inspection process of a display device according to one or more embodiments and is a diagram for schematically explaining a light emitting element inspection device.

Hereinafter, a method of manufacturing a display device will be described with reference to FIGS. 11-24.

Referring to FIG. 11, a method of manufacturing a display device according to one or more embodiments includes forming a light emitting element rod LED on the growth substrate (e.g., a base substrate) BSUB (S110), forming a protective layer INS and a contact electrode CTE covering a top surface of the light emitting element rod LED (S120), forming a metal layer ML disposed on a side of the light emitting element rod LED and the growth substrate BSUB on which the light emitting element rod LED is not disposed (S130), forming a contact pad CPD connected with the metal layer ML on the growth substrate BSUB (S140), applying a test power to the contact electrode CTE and the contact pad CPD (S150), transferring the light emitting element LE to the circuit board (S160), and forming a common electrode CE in side contact with the metal layer ML of the light emitting element LE (S170). Here, the steps from step S110 to step S150 may be referred to as the light emitting element inspection steps.

Hereinafter, a method of manufacturing the display device shown in FIGS. 12-24 will be described in conjunction with FIG. 11.

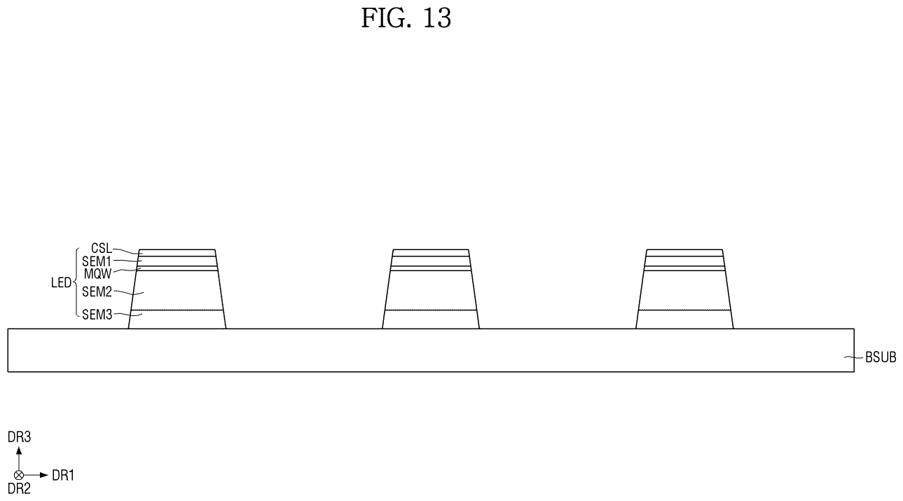

Referring to FIGS. 12 and 13, a light emitting element rod LED is formed on the growth substrate BSUB. (S110 in FIG. 11)

First, the growth substrate BSUB is prepared. The growth substrate BSUB may be a sapphire substrate (Al₂O₃) and/or a silicon wafer containing silicon. However, it is not limited thereto, and one or more embodiments will be described by way of example when the growth substrate BSUB is a sapphire substrate.

A plurality of semiconductor material layers are formed on the growth substrate BSUB. A plurality of semiconductor material layers grown by the epitaxial method may be formed by growing a seed crystal. Here, the method of forming the semiconductor material layer may be electron beam deposition, physical vapor deposition (PVD), chemical vapor deposition (CVD), plasma laser deposition (PLD), dual-type thermal evaporation, sputtering, metal organic chemical vapor deposition (MOCVD), and/or the like, and may be preferably formed by metal organic chemical vapor deposition (MOCVD). However, it is not limited thereto.

The precursor material for forming the plurality of semiconductor material layers is not particularly limited within a range that may be conventionally selected to form the target material. In one example, the precursor material may be a metal precursor containing an alkyl group such as a methyl group and/or an ethyl group. For example, it may be a compound such as trimethyl gallium (Ga(CH₃)₃), trimethyl aluminum (Al(CH₃)₃), and/or triethyl phosphate ((C₂H₅)₃PO₄), but is not limited thereto.

A third semiconductor material layer SEM₃L is formed on the growth substrate BSUB. In the drawing, the third semiconductor material layer SEM₃L is shown as one layer, but the present disclosure is not limited to this, and a plurality of layers may be formed. The third semiconductor material layer SEM₃L may be disposed to reduce the difference in lattice constant between the second semiconductor material layer SEM₂L and the growth substrate BSUB. In one or more embodiments, the third semiconductor material layer SEM₃L may include an undoped semiconductor and may be a material that is not doped as N-type or P-type. In one or more embodiments, the third semiconductor material layer SEM₃L may be undoped InAlGaN, GaN, AlGaN, InGaN, AlN, and/or InN, but is not limited thereto.

The second semiconductor material layer SEM₂L, the active material layer MQWL, the first semiconductor material layer SEM1L are sequentially formed on the third semiconductor material layer SEM₃L using the above-described method. In one or more embodiments, a superlattice material layer may be formed between the second semiconductor material layer SEM₂L and the active material layer MQWL. Furthermore, an electron blocking material layer may be formed between the active material layer MQWL and the first semiconductor material layer SEM1L. In one or more embodiments, a current spreading material layer CSLL may be further included on the first semiconductor material layer SEM1L. The current spreading material layer CSLL may be made of a transparent conductive material (TCO), such as indium tin oxide (ITO) and/or indium zinc oxide (IZO), which may transmit light.

Next, referring to FIG. 13, a plurality of semiconductor material layers are etched through an etching process using a mask to form a light emitting element rod LED.

Specifically, a mask pattern is formed on the first semiconductor material layer SEM1L and the current spreading material layer CSLL. The mask pattern may be a hard mask containing an inorganic material and/or a photoresist mask containing an organic material. The mask pattern prevents the underlying plurality of semiconductor material layers from being etched. Next, a portion of the plurality of semiconductor material layers is etched using the plurality of mask patterns as a mask to form a plurality of light emitting element rods LED.

The semiconductor material layers may be etched by conventional methods. For example, the process of etching the semiconductor material layers may be dry etching, wet etching, reactive ion etching (RIE), deep reactive ion etching (DRIE), inductively coupled plasma reactive ion etching (ICP-RIE), and/or the like. In the case of dry etching methods, anisotropic etching is possible and may be suitable for vertical etching. When using the etching method described above, the etching etchant may be Cl₂ and/or O₂. However, it is not limited to this.

The plurality of semiconductor material layers overlapping the mask pattern are not etched but are formed into light emitting element rods LED. Accordingly, the light emitting element rod LED is formed including the third semiconductor layer SEM3, the second semiconductor layer SEM2, the active layer MQW, the first semiconductor layer SEM1, and the current spreading layer CSL.

Next, forming a protective layer INS and a contact electrode CTE covering the top surface of the light emitting element rod LED. (S120)

For example, a photoresist PR is formed up to the side of the light emitting element rod LED. The photoresist PR may be formed lower than the height of the light emitting element rod LED in the third direction DR3. For example, the photoresist PR may be formed lower than the height of the first semiconductor layer SEM1 and the active layer MQW of the light emitting element rod LED, and higher than the boundary between the third semiconductor layer SEM3 and the second semiconductor layer SEM2.

A protective material layer INSL is applied entirely to the growth substrate BSUB on which the photoresist PR is formed. The protective material layer INSL may be disposed on the top and some sides of the light emitting element rod LED. Afterwards, the photoresist PR is removed to form a protective layer INS on the top surface and some sides of the light emitting element rod LED.

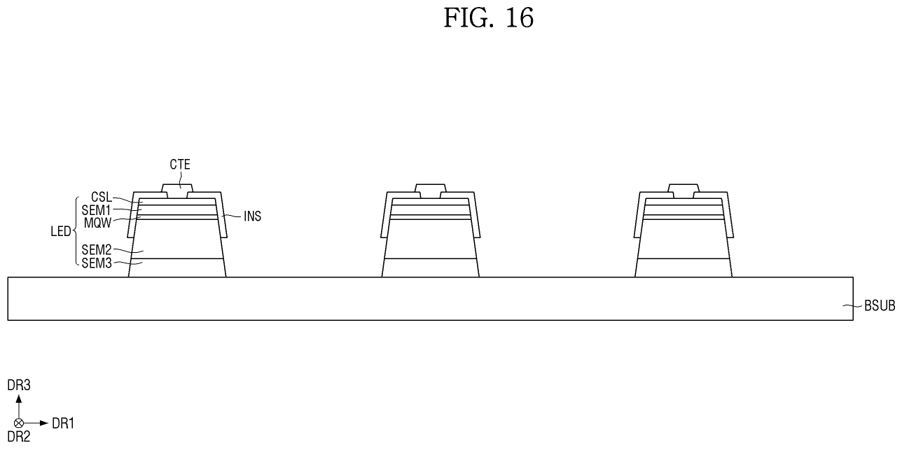

Next, as shown in FIGS. 15 and 16, a through hole h1 is formed in the protective layer INS on the top surface of the light emitting element rod LED. Afterwards, an electrode material layer is applied to cover the through hole h1 and then etched using a mask to form a contact electrode CTE. The contact electrode CTE may be formed to be wider than the width of the through hole h1 and narrower than the width of one side of the light emitting element rod LED.

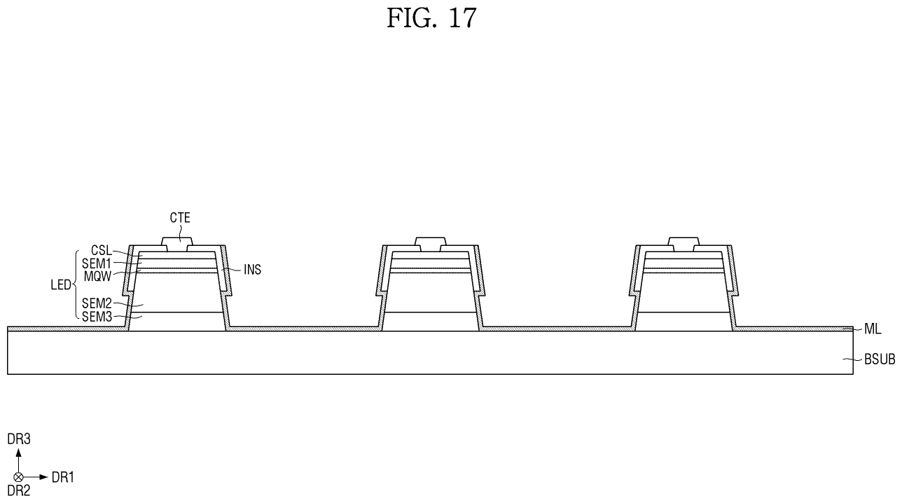

Next, referring to FIG. 17, a metal layer ML is formed on the entire surface of the growth substrate BSUB excluding the top surface of the light emitting element rod LED. (S130 in FIG. 11)

The metal layer ML is a conductive metal and may be disposed on the side of the light emitting element rod LED and on the growth substrate BSUB on which the light emitting element rod LED is not disposed. In one or more other embodiments, metal layer ML may be disposed on the side of the light emitting element rod LED and on the growth substrate BSUB on which none of the plurality of light emitting elements rods LED are located.

The metal layer ML is around (e.g., surrounds) the side surfaces of the plurality of light emitting element rods LED and may be a common layer disposed on the entire surface of the growth substrate BSUB. Accordingly, the metal layer ML and the plurality of light emitting element rods LED may be electrically connected.

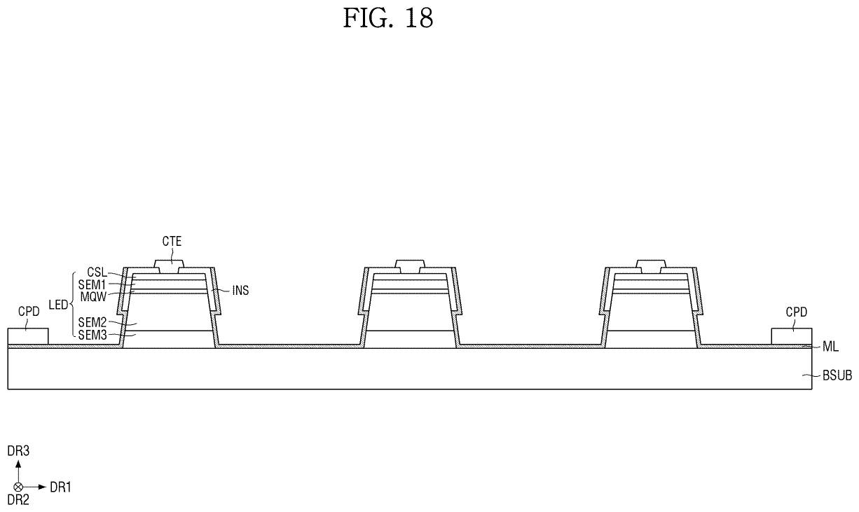

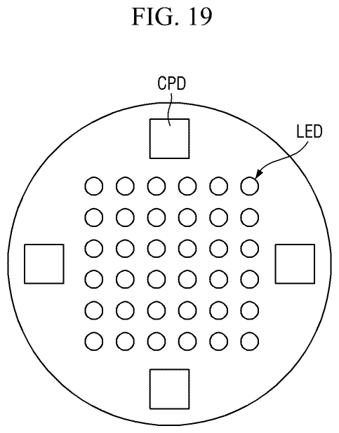

Thereafter, referring to FIGS. 18 and 19, one or more contact pads CPD connected to the metal layer ML may be formed on the growth substrate BSUB. (S140 in FIG. 11)

Referring to FIG. 18, the contact pad CPD is disposed on the metal layer ML but is not limited thereto. Additionally, in one or more embodiments, the contact pad CPD may be omitted.

One or more contact pads CPD may be formed on the growth substrate BSUB. Referring to FIG. 19, one contact pad CPD is formed on the top, bottom, left, and right sides of the growth substrate BSUB, respectively, but is not limited to this. The position, size, or number of contact pads CPD may be changed according to convenience.

Referring to FIG. 20, a test power may be applied to the contact electrode CTE and contact pad CPD of the light emitting element rod LED. (S150 in FIG. 11)

Before describing the application of test power, the light emitting element inspection device will be described with reference to FIG. 20.

The light emitting element inspection device may include a contact pad CPD, a power application portion 50, an image sensor 30, and a control portion 60.

The power application portion 50 includes a plurality of probes 51 and 52 and applies test power to the light emitting element rods LED to be inspected using the plurality of probes 51 and 52.

For example, after contacting the first probe 51 of the power application portion 50 with the contact electrode CTE and contacting the second probe 52 of the power application portion 50 with the contact pad CPD, the power application portion 50 applies test power to the plurality of light emitting element rods LED through the first probe 51 and the second probe 52. The power application portion 50 may be driven by a signal applied from the outside, and when the power is applied, the test power is applied to the plurality of light emitting element rods LED to be inspected to check whether the plurality of light emitting element rods LED are defective. A normal light emitting element rods LED may light up when test power is applied.

One or more image sensors 30 are disposed on one side of the light emitting element rods LED to acquire images of light emitted from the light emitting element rods LED. The image sensor 30 may be, for example, a camera. Here, the camera may include, but is not limited to, an area scan camera or a line scan camera, and any device that may photograph an object other than a camera may be used.

The control portion 60 is electrically connected to the image sensor 30 and the power application portion 50 to transmit and receive information. The control portion 60 may control the operation of the image sensor 30 and the power application portion 50. The information transmitted and received by the control portion 60 may include, for example, a reference image for determining a defect in a light emitting element rods LED. The reference image may be stored in the control portion 60 prior to inspection. The control portion 60 may determine lighting defects through the image acquired through the image sensor 30.

For example, the control portion 60 may determine whether the light emitting element rods LED is defective by comparing one or more of the luminance and illuminance on the acquired image with a preset standard. For example, if one or more of the luminance and illuminance of any of the light emitting element rods LED in the acquired image is significantly lower than other light emitting element rods LED, the light emitting element rods LED may be determined to be defective.

For example, when a malfunction is detected in some light emitting element rods LED, a process for removing the corresponding light emitting element rods LED may be performed separately.

According to one or more embodiments, the metal layer ML formed on the growth substrate BSUB and the light emitting element rods LED are electrically connected to inspect whether the light emitting element rods LED are defective before being transferred to the circuit board.

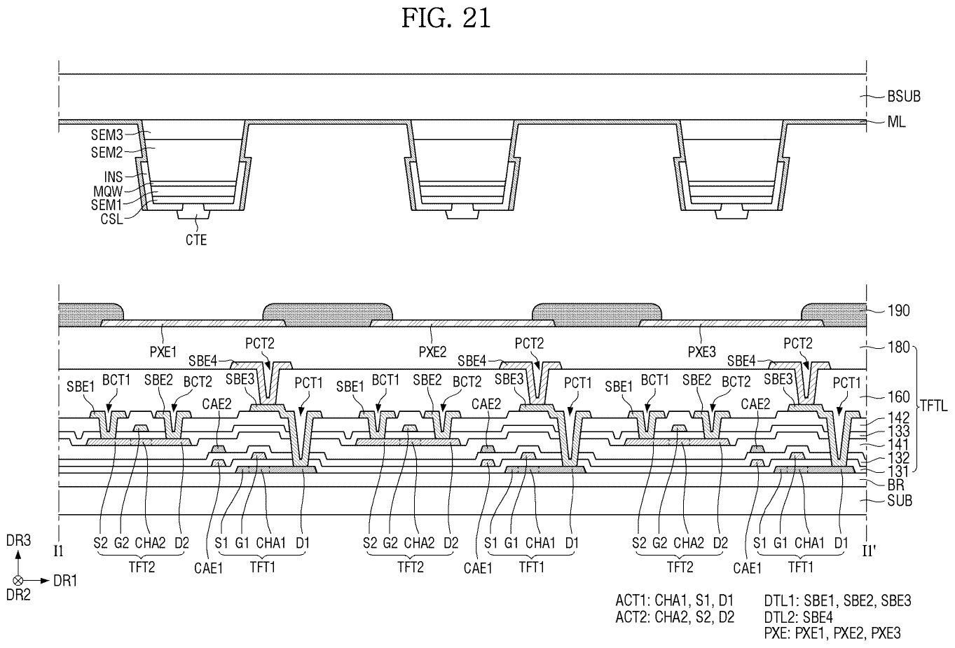

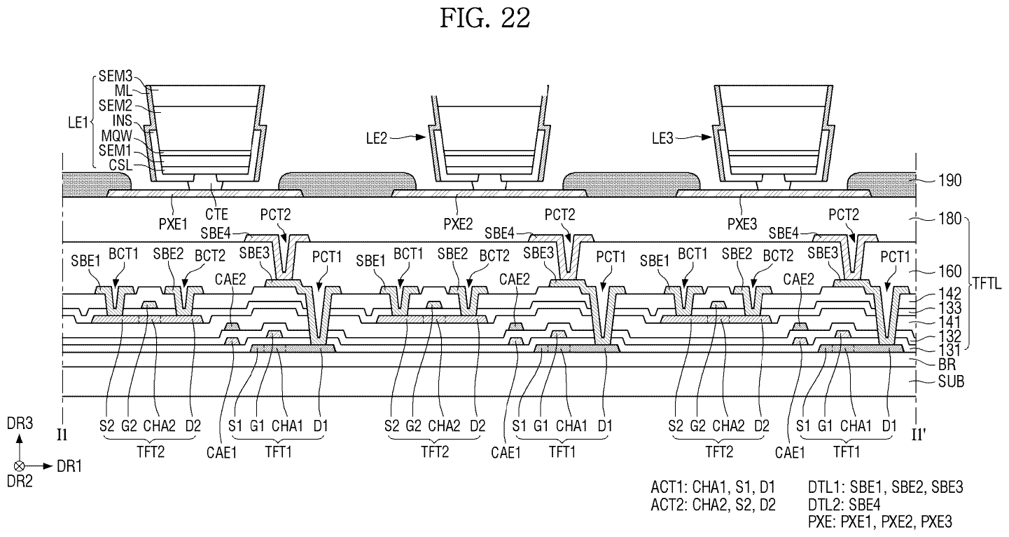

Next, referring to FIGS. 21 and 22, a light emitting element LE on the inspected growth substrate BSUB is transferred to a circuit board (e.g., the substrate SUB). (S160 in FIG. 11)

A pixel circuit PXC and a pixel electrode PXE electrically connected to the pixel circuit PXC may be disposed on the circuit board (e.g., the substrate SUB).

For example, the light emitting elements LE on the inspected growth substrate BSUB may be aligned on each pixel electrode PXE. Although the pixel electrode PXE and the light emitting element LE are illustrated as having a one-to-one correspondence, this is only an example for explanation, and multiple light emitting elements LE may be disposed on one pixel electrode PXE.

Thereafter, the contact electrode CTE of the light emitting element LE is bonded by contacting the pixel electrode PXE of the circuit board (e.g., the substrate SUB).

For example, by irradiating the contact electrode CTE with a laser to heat the contact electrode CTE to a melting temperature of the contact electrode CTE, the circuit board (e.g., the substrate SUB) and the contact electrode CTE may be pressurized melt bonded. Here, in pressure melt bonding, the contact electrode CTE is heated and melted by irradiation of the laser, and the light emitting element LE and the pixel electrode PXE are melted and mixed, and cooled to a solid state when the laser supply is terminated. Although the melted and mixed state is cooled and solidified, the conductivity of the light emitting element LE and the pixel electrode PXE is maintained, so the pixel electrode PXE and the light emitting element LE may be electrically and physically connected, respectively. In one or more embodiments, an example of irradiating a laser to the contact electrode CTE has been described, but bonding may be performed by adding a separate connection electrode between the contact electrode CTE and the pixel electrode PXE.

Thereafter, a laser is irradiated to the growth substrate BSUB to separate the growth substrate BSUB from the plurality of light emitting elements LE. The growth substrate BSUB may be separated by a laser lift off (LLO) process. The laser lift-off process uses a laser, and a KrF excimer laser (248 nm wavelength) may be used as the source. The energy density of the excimer laser is in the range of about 550mJ/cm² to 950 mJ/cm², and the incident area may be in the range of 50×50 μm² to 1×1 cm² but is not limited thereto. By irradiating a laser to the growth substrate BSUB, the growth substrate BSUB may be separated from the light emitting element LE. In one or more embodiments, the light emitting element LE on the growth substrate BSUB is directly transferred to the circuit board (e.g., the substrate SUB), but the present disclosure is not limited thereto. For example, the light emitting element LE on the growth substrate BSUB may be transferred to a separate relay substrate(s) and then transferred to the circuit board (e.g., the substrate SUB).

The light emitting element LE transferred to the circuit board (e.g., the substrate SUB) may be arranged on the circuit board (e.g., the substrate SUB) in the reverse order in which it was grown on the growth substrate BSUB. For example, a current spreading layer CSL, a first semiconductor layer SEM1, an active layer MQW, and a second semiconductor layer SEM2, and a third semiconductor layer SEM3, may be sequentially stacked on the pixel electrode PXE.

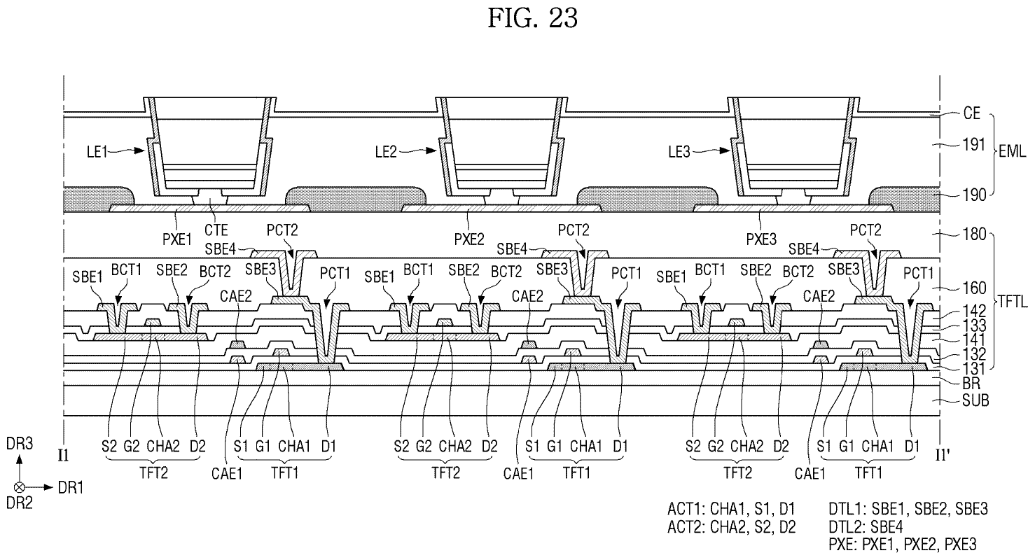

Next, referring to FIG. 23, a common electrode CE is formed to make side contact with the metal layer ML of the light emitting element LE. (S170 in FIG. 11)

For example, a third organic layer 191 is formed on the side of the light emitting element LE. The third organic layer 191 may be referred to as a planarization film because it flattens the steps between the light emitting elements LE. The third organic layer 191 may be formed of an inorganic film such as silicon oxide (SiO₂), aluminum oxide (Al₂O₃), and/or hafnium oxide (HfOₓ) but is not limited thereto. The third organic layer 191 is formed to have a thickness lower than the height of the light emitting element LE so that one end of the light emitting element LE is exposed. For example, it may be formed by applying the coating to cover all of the plurality of light emitting elements LE and then patterning them using a mask pattern to expose the upper layer of the plurality of light emitting elements LE.

Next, the common electrode CE is formed on the third organic layer 191. The common electrode CE may be in direct contact with the metal layer ML of the light emitting element LE on the side of the light emitting element LE. The common electrode CE may have an opening on the light emitting element LE. The common electrode CE may include molybdenum (Mo), aluminium (Al), chromium (Cr), gold (Au), titanium (Ti), nickel (Ni), neodymium (Nd), and/or copper (Cu). Further, the common electrode CE may be formed of a transparent conductive oxide (TCO) such as indium tin oxide (ITO) and/or indium zinc oxide (IZO), but the common electrode CE may not be transparent as it has an opening on the top surface of the light emitting element LE.

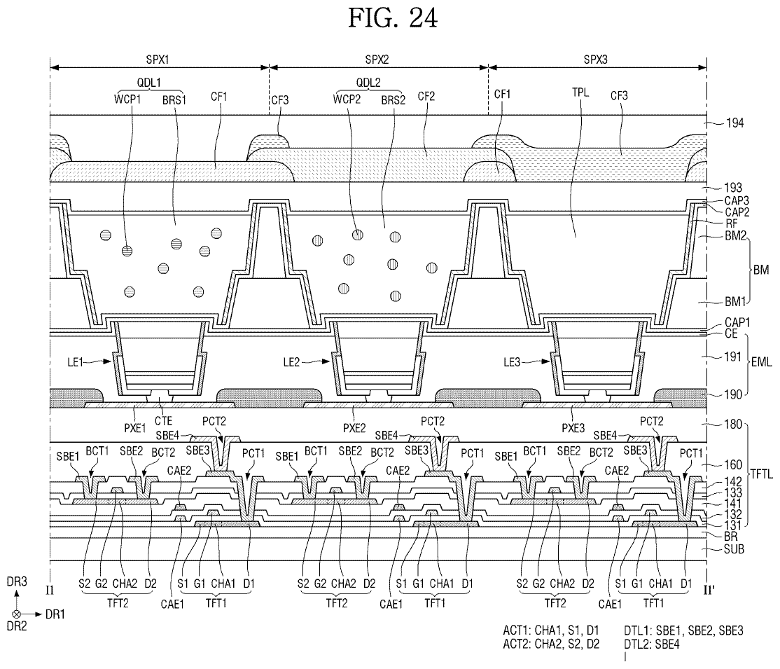

Then, referring to FIG. 24, the light blocking layer BM, the first and second light conversion layers QDL1 and QDL2, light transmission layer TPL, and color filters CF1, CF2, and CF3 are formed.

For example, a first capping layer CAP1 is formed on the common electrode CE, a first light blocking layer BM1 is formed on the first capping layer CAP1, and a second light blocking layer BM2 is formed on the first light blocking layer BM1. The first light blocking layer BM1 and the second light blocking layer BM2 may overlap the bank layer 190 in the third direction DR3 and may not overlap the plurality of light emitting elements LE. A length of the first light blocking layer BM1 in the first direction DR1 or a length in the second direction DR2 may be wider than a length of the second light blocking layer BM2 in the first direction DR1 or a length in the second direction DR2.

Then, a second capping layer CAP2 is formed on the first capping layer CAP1 and the light blocking layer BM, and a reflective layer RF is formed on the second capping layer CAP2 disposed on the side surface of the first light blocking layer BM1 and the side surface of the second light blocking layer BM2.

Then, a first light conversion layer QDL1 is formed in the area corresponding to the first sub-pixel SPX1, a second light conversion layer QDL2 is formed in the area corresponding to the second sub-pixel SPX2, and a light transmission layer TPL is formed in the area corresponding to the third sub-pixel SPX3 in the areas separated from the first light blocking layer BM1 and the second light blocking layer BM2.

Then, a third capping layer CAP3 is formed on the second capping layer CAP2, the first light conversion layer QDL1, the second light conversion layer QDL2, and the light transmission layer TPL, and a fourth organic layer 193 is formed on the third capping layer CAP3.

Then, a plurality of color filters CF1, CF2, and CF3 are formed on the fourth organic layer 193, and a fifth organic layer 194 is formed on the plurality of color filters CF1, CF2, and CF3.

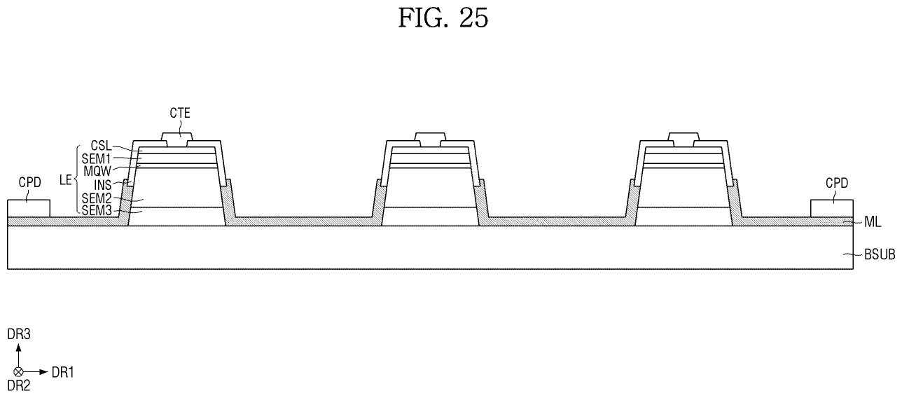

FIG. 25 is a cross-sectional view of a step of the inspection process to illustrate a light emitting element inspection method according to one or more embodiments. FIG. 25 is a light emitting element inspection method corresponding to the light emitting element LE of FIG. 9.

Referring to FIG. 25, a metal layer ML may be disposed on the entire surface of the growth substrate BSUB, around (e.g., surrounding) the third semiconductor layer SEM3 and at least a portion of the second semiconductor layer SEM2 and in direct contact with some portions of the sides of the light emitting element LE. The contact pad CPD may be formed to directly contact the metal layer ML. The defects in the light emitting element LE may be inspected by applying a test voltage to one or more contact pads CPD and the contact electrodes CTE.

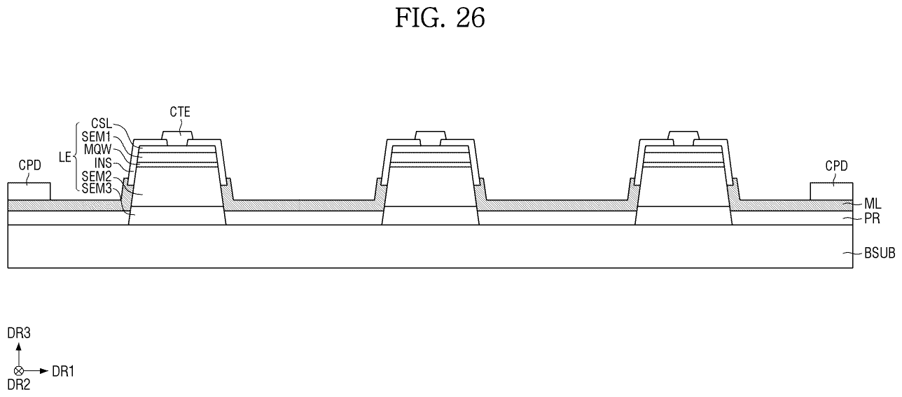

FIGS. 26-28 are cross-sectional views of each step of the inspection process to illustrate a light emitting element inspection method according to one or more embodiments. FIGS. 26-28 are a light emitting element inspection method corresponding to the light emitting element LE of FIG. 10.

Referring to FIG. 26, a photoresist PR may be formed on the growth substrate BSUB to be lower than the height of the boundary between the second semiconductor layer SEM2 and the third semiconductor layer SEM3 of the light emitting element LE in the third direction DR3.

the photoresist PR may be disposed on the formed growth substrate BSUB in direct contact with and around (e.g., surrounding) at least a portion of the third semiconductor layer SEM3 of the light emitting element LE and may be disposed on the entire surface of the growth substrate BSUB. Next, the metal layer ML and the contact pads CPD may be formed, and then the defects in the light emitting element LE may be inspected by applying a test voltage to one or more contact pads CPD and the contact electrodes CTE.

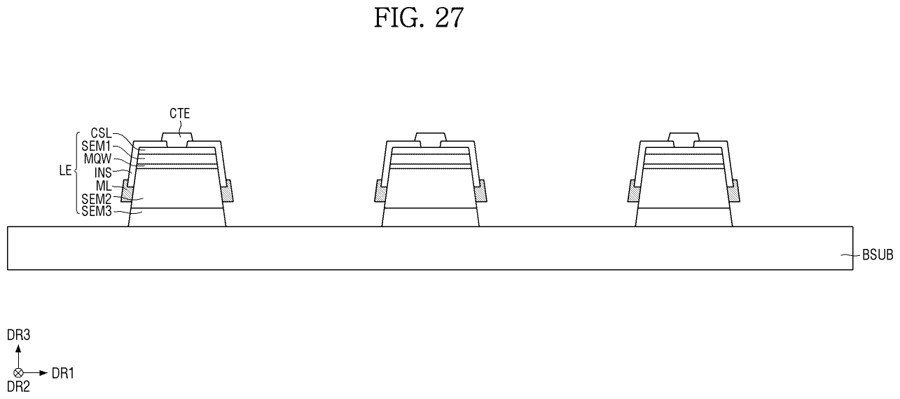

Afterwards, as shown in FIG. 27, the photoresist PR may be removed. At this time, along with the removal of the photoresist PR, the metal layer ML formed on the photoresist PR is removed, and only the metal layer ML disposed on the side of the light emitting element LE remains. Accordingly, the metal layers ML disposed on the side of each light emitting element LE are electrically separated from each other.

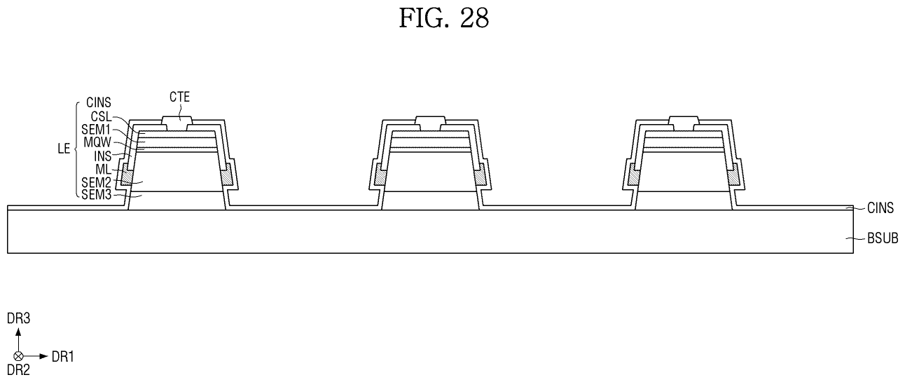

As shown in FIG. 28, a cover protective layer CINS may be formed on the metal layer ML and the protective layer INS to be around (e.g., to surround) the side surfaces of the plurality of semiconductor layers and the side and top surfaces of the current spreading layer CSL. For example, a cover protective layer CINS may be applied entirely to the growth substrate BSUB on which the metal layer ML is formed.

However, the aspects of the present disclosure are not restricted to the one set forth herein. The above and other aspects of the present disclosure will become more apparent to one of daily skill in the art to which the present disclosure pertains by referencing the claims, with functional equivalents thereof to be included therein.

What is claimed is:

1. A light emitting element inspection method comprising:
forming a plurality of light emitting element rods by etching a plurality of semiconductor material layers stacked on a growth substrate;
forming a protective layer covering a portion of a top surface and a portion of side surfaces of the plurality of light emitting element rods and a contact electrode on the protective layer;
forming a metal layer on the side surfaces of the plurality of light emitting element rods and on a portion of the growth substrate on which none of the plurality of light emitting elements rods is located;
forming a contact pad connected to the metal layer on the growth substrate; and
applying a test power to the contact electrode and the contact pad.

2. The method of claim 1, the forming the light emitting element rod comprises:
sequentially forming a third semiconductor material layer, a second semiconductor material layer, an active material layer, and a first semiconductor material layer on the growth substrate; and
patterning the third semiconductor material layer, the second semiconductor material layer, the active material layer, and the first semiconductor material layer to form the plurality of light emitting element rods.

3. The method of claim 2, wherein the forming the protective layer covering the portion of the top surface and the portion of the side surfaces of the plurality of light emitting element rods and the contact electrode on the protective layer comprises:
forming a photoresist covering at least a portion of the second semiconductor material layer on an entire surface of the growth substrate;
applying a protective material layer covering the plurality of light emitting element rods and the photoresist;
forming the protective layer covering the top surface of the plurality of light emitting element rods, and side surfaces of the first semiconductor material layer and the active material layer; and
forming a through hole in a portion on the top surface of each of the plurality of light emitting element rods of the protective layer and forming the contact electrode covering the through hole.

4. The method of claim 3, wherein the forming the metal layer on the side surfaces of the plurality of light emitting element rods and on the portion of the growth substrate on which none of the plurality of light emitting elements rods is located, comprises:
forming the metal layer on the entire surface of the growth substrate except for the top surface of the plurality of light emitting element rods using a mask, the metal layer being in direct contact with the second semiconductor material layer of the plurality of light emitting element rods and connected to the plurality of light emitting element rods.

5. The method of claim 1, wherein the applying the test power to the contact electrode and the contact pad comprises:
supplying the test power to at least a portion of the plurality of light emitting element rods using a probe on one side of the plurality of light emitting element rods;
acquiring an image of light emitted from the plurality of light emitting element rods to which the test power is supplied on an other side of the plurality of light emitting element rods by an image sensor; and
determining whether the plurality of light emitting element rods are defective by a control portion comparing the acquired image with a pre-stored reference image.

6. A display device manufacturing method comprising:
forming a plurality of light emitting element rods by etching a plurality of semiconductor layers stacked on a growth substrate;
forming a protective layer covering a portion of a top surface and a portion of side surfaces of the plurality of light emitting element rods and a contact electrode on the protective layer;
forming a metal layer on the side surfaces of the plurality of light emitting element rods and on a portion of the growth substrate on which none of the plurality of light emitting elements rods is located;
forming a contact pad connected to the metal layer on the growth substrate;
applying a test power to the contact electrode and the contact pad;
transferring a plurality of light emitting elements comprising the plurality of light emitting element rods, the protective layer, and the metal layer to a circuit board; and
forming a common electrode in contact with the metal layer of the plurality of light emitting elements on a side surface of the plurality of light emitting elements.

7. The method of claim 6, wherein the forming the plurality of light emitting element rods comprises:
sequentially forming a third semiconductor material layer, a second semiconductor material layer, an active material layer, and a first semiconductor material layer on the growth substrate; and
forming the plurality of light emitting element rods by patterning the third semiconductor material layer, the second semiconductor material layer, the active material layer, and the first semiconductor material layer.

8. The method of claim 7, wherein the forming the protective layer covering the portion of the top surface and the portion of the side surfaces of the plurality of light emitting element rods and the contact electrode on the protective layer comprises:
forming a photoresist covering at least a portion of the second semiconductor material layer on an entire surface of the growth substrate;
applying a protective material layer covering the plurality of light emitting element rods and the photoresist;
forming the protective layer covering the top surface of the plurality of light emitting element rods, and side surfaces of the first semiconductor material layer and the active material layer; and
forming a through hole in a portion on the top surface of each of the plurality of light emitting element rods of the protective layer, and forming the contact electrode covering the through hole.

9. The method of claim 8, wherein the forming the metal layer on the side surfaces of the plurality of light emitting element rods and on the portion of the growth substrate on which none of the plurality of light emitting elements rods is located comprises:
forming the metal layer on the entire surface of the growth substrate except for the top surface of the plurality of light emitting element rods using a mask, the metal layer being in direct contact with the second semiconductor material layer of the plurality of light emitting element rods and connected to the plurality of light emitting element rods.

10. The method of claim 8, wherein the forming the metal layer on the side surfaces of the plurality of light emitting element rods and on the portion of the growth substrate on which none of the plurality of light emitting elements rods is located comprises:
forming the photoresist covering at least a portion of the third semiconductor material layer on the entire surface of the growth substrate; and
forming the metal layer covering the plurality of light emitting element rods and the photoresist.

11. The method of claim 10, wherein between the applying the test power and the transferring the plurality of light emitting elements to the circuit board, the method further comprises:
removing the photoresist; forming a cover protective layer around the side surfaces and the top surface of the plurality of light emitting element rods; and
forming an opening in the cover protective layer exposing the contact electrode.

12. The method of claim 6, wherein a plurality of pixel circuit portions is on the circuit board,
wherein each of the plurality of pixel circuit portions comprises a pixel electrode located at a top surface of the plurality of pixel circuit portions, and
wherein the transferring the plurality of light emitting elements comprising the plurality of light emitting element rods, the protective layer, and the metal layer to the circuit board comprises:
placing the contact electrode of the light emitting element on the pixel electrode and electrically connecting and bonding the contact electrode on the circuit board.

13. The method of claim 12, wherein the circuit board further comprises a bank around the pixel electrode, wherein the method further comprises:
forming a light blocking layer on the common electrode overlapping the bank;
forming a first wavelength conversion layer in an area corresponding to a first sub-pixel of the display device, forming a second wavelength conversion layer in an area corresponding to a second sub-pixel of the display device, and forming a light transmission layer in an area corresponding to a third sub-pixel of the display device from among areas compartmentalized by the light blocking layer; and
forming a first color filter on the first wavelength conversion layer, forming a second color filter on the second wavelength conversion layer, and forming a third color filter on the light transmission layer.

14. The method of claim 6, wherein the common electrode does not overlap the top surface of the light emitting element.

15. The method of claim 6, the applying the test power to the contact electrode and the contact pad comprises:
supplying the test power to at least a portion of the plurality of light emitting element rods using a probe on one side of the plurality of light emitting element rods;
acquiring an image of light emitted from the plurality of light emitting element rods to which the test power is supplied on an other side of the plurality of light emitting element rods by an image sensor; and
determining whether the plurality of light emitting element rods is defective by a control portion comparing the image acquired by the image sensor with a reference image.

16. A light emitting element inspection device for inspecting illumination of a plurality of light emitting elements on a growth substrate, the light emitting element inspection device comprising:
a contact pad on the growth substrate and electrically connected to a metal layer on side surfaces of the plurality of light emitting elements and a portion of the growth substrate on which none of the plurality of light emitting elements is located; and
a probe and a power application portion configured to apply a test power to a contact electrode of the plurality of light emitting elements and the contact pad through the probe.

17. The device of claim 16, further comprising an image sensor on one side of the plurality of light emitting elements to acquire an image of light emitted from the plurality of light emitting elements; and
a control portion for determining whether the plurality of light emitting elements is defective by comparing the image acquired by the image sensor with a reference image.

18. The device of claim 16,
wherein a light emitting element from among the plurality of light emitting elements comprises a second semiconductor layer, a first semiconductor layer, and an active layer between the second semiconductor layer and the first semiconductor layer, and
wherein the metal layer is in direct contact with the second semiconductor layer and is spaced from the contact electrode.

19. The device of claim 18,
wherein the light emitting element further comprises a protective layer around a top surface and a side surface of the first semiconductor layer and a side surface of the active layer,
wherein the protective layer includes a through hole in a portion on the top surface of the first semiconductor layer of the protective layer, and
wherein the contact electrode is electrically connected to the first semiconductor layer through the through hole.

20. The device of claim 19,
wherein the metal layer extends over the protective layer and is around the side surfaces of the first semiconductor layer and the active layer.
